(19) United States
(12) Patent Application Publication
(10) Pub. No.: US 2010/0092892 A1
(43) Pub. Date: Apr. 15, 2010

(54) PHOTOPOLYMERIZED RESIN LAMINATE AND METHOD FOR MANUFACTURING BOARD HAVING BLACK MATRIX PATTERN

(76) Inventors: Hideaki Kurita, Tokyo (JP); Hideki Matsuda, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/521,301

(22) PCT Filed: Dec. 21, 2007
(86) PCT No.: PCT/JP2007/074730

§ 371 Date: Dec. 14, 2009

(30) Foreign Application Priority Data
Dec. 26, 2006 (JP) 2006-349497

(51) Int. Cl. G03F 7/00; B32B 27/00; B05D 5/06

(52) U.S. Cl. 430/321; 428/411.1; 428/422; 427/407.1; 156/230; 430/325

(57) ABSTRACT

An object is to manufacture a substrate having a black matrix pattern with excellent ink repellency on the surface by an easy method. A fluorine-containing compound coated film in which 1 to 60 mm³ of an organic material layer containing 30 to 100% of a fluorine-containing compound is provided on a supporting film per 1 m² of the supporting film and the organic material layer has a contact angle to xylene of 20 degrees or more is used.

### TECHNICAL FIELD

The present invention relates to a substrate having a black matrix for a liquid crystal display and a manufacturing method using the same, which is useful for manufacturing a color filter.

### BACKGROUND ART

Liquid crystal displays generally include a member called a color filter which gives color to backlight. Such color filters are composed of a substrate, color pixels of red, green and blue on the substrate and a black matrix separating the pixels. Black matrices are generally positioned between color pixels in the form of lattices in order to prevent errors, improve contrast or avoid mixing of colors in TFT.

A common method for manufacturing a color filter is briefly described below. First, a material layer for forming a black matrix is formed on a substrate composed of a glass base using a liquid or film material. Next, a desired pattern is formed by a photolithographic process. Then, a color resist liquid material is applied, and exposure and development are carried out by a photolithographic process for each color of red, blue and green, thereby manufacturing a color filter.

This method, however, is expensive because it is necessary to repeat photolithographic processes three times for each color of the color resist layers. Also, the method has the problem of low production yields due to long steps.

To compensate for such defects, a method for printing a color resist layer by an inkjet process is proposed (see Patent Document 1). Since the process can reduce photolithographic steps and form the colors at once, the production cost can be greatly reduced.

An example of such a process is shown in FIG. 1. FIG. 1(a) illustrates a step of forming a black matrix layer 3 on a glass substrate 4 and applying a color resist ink 2 through an inkjet head 1. After applying a color resist ink (hereinafter also referred to as “ink”) to each matrix (FIG. 1(b)), drying treatment is performed according to need, and the resist ink is hardened by irradiation of light, heat treatment or both (FIG. 1(c)). In the process, the top surface of the black matrix layer (the side opposite from the side coming into contact with a substrate) is required to repel ink, namely, must have so-called ink repellency, to avoid mixing of ink. On the other hand, it is desired that side surfaces have good wettability to ink. This is because when ink is repelled at side surfaces, space is left at the interface between ink and black matrix, causing decoloration.

For these conflicting objectives, Patent Document 2 discloses a technique in which black resist is coated on a glass substrate and dried, and an ink repellent treating agent is further coated on the black resist layer by spin coating and dried. Patent Document 3 discloses a technique in which a light transmissive resin layer containing a specific fluorine compound is provided on a light shielding layer which is a black resin layer. However, since spin coating a once spin-coated surface requires control of film thickness again and is difficult to be coated on recent larger substrates, an easier technique of giving ink repellency on the top surface of a black matrix layer has been strongly desired.

Patent Document 4 discloses a technique in which a transfer film containing a silicone component is formed at the interface between a transfer layer composed of a photopolymerizable resin composition and a base film, and the material is laminated on a glass substrate. However, the process of forming a transfer film containing a silicone component at the interface between a transfer layer and a base film requires a step of forming a photopolymerizable resin composition layer on a film coated with the silicone component. To form a photopolymerizable resin composition layer, it is necessary to apply a solution of a photopolymerizable resin composition, which is prepared by dissolving a photopolymerizable resin composition in a solvent, to the silicone component. Therefore, when such a silicone component and a solution of a photopolymerizable resin composition are incompatible, forming a perfect photopolymerizable resin composition layer on a film coated with the silicone component is difficult. In addition, when ink repellency is given on the top surface of a black matrix layer by such a silicone component, the ink repellency was insufficient for some ink components.

Patent Document 5, on the other hand, discloses a film for dry photoresist, which is a film with a fluorine-containing compound provided on the surface. However, since the fluorine-containing compound is fixed to the film by heat, transferring the fluorine compound of the film to another material to give ink repellency is difficult. Also, the reference does not contain any specific description of the relevance of the film thickness of the fluorine-containing compound and film forming properties of thin film resist on the film.

Examples of usage of films on which a fluorine-containing compound is provided include direct usage of the films, which is commonly known, such as mold releasing films, surface protection films, releasing sheets for electronic parts, antireflective films and protection films for dry films. As an example of transferring a layer containing a fluorine compound to be used for manufacturing a color filter, Patent Documents 6 to 8 disclose an example in which a transfer layer composed of an ink-repellent first layer and an ink-philic second layer is transferred to form partitions for inkjet. These documents disclose that a fluorine compound is added to a photosensitive resin composition and the resultant is used as the ink-repellent first layer and that a preferred film thickness is 0.1 μm to 1 μm. To remove the ink-repellent layer by development, developability must be considered upon blending. For that reason, ink repellency on the first layer surface was insufficient. Also, as a process for forming an ink-philic second layer on an ink-repellent first layer, a known coating process is described. However, the ink repellent layer has a characteristic of easily repelling such an ink-philic material. Thus, direct coating of an ink-philic layer on an ink repellent layer was virtually difficult.

Patent Document 1: JP-A-59-75205

Patent Document 2: JP-A-09-203803

Patent Document 3: JP-A-07-035916

Patent Document 4: JP-A-2002-131525

Patent Document 5: JP-A-2004-53897

Patent Document 6: JP-A-2002-139612

Patent Document 7: JP-A-2002-139613

Patent Document 8: JP-A-2002-139614

### DISCLOSURE OF THE INVENTION

### Problems to be Solved by the Invention

An object of the present invention is to prepare a black matrix pattern with excellent ink repellency only on the top surface by an easy method with excellent pattern forming properties.

### Means for Solving the Problems

As a result of intensive studies to solve the above problem, a photopolymerizable resin layered film composed of a specific fluorine-containing compound layer and a photopolymerizable resin layer provided on a supporting film in that order and a method for manufacturing a substrate having a black matrix pattern using the laminate have been found, and the present invention has been accomplished.

Accordingly, the present invention is as follows:

(1) A photopolymerizable resin layered film comprising a fluorine-containing compound layer and a photopolymerizable resin layer provided on a supporting film in that order,

characterized in that the fluorine-containing compound layer is formed by coating 1 to 60 mm³ of a composition containing 30 to 100% by mass of a fluorine-containing compound per 1 m² of the supporting film and has a contact angle to xylene of 20 degrees or more, and the photopolymerizable resin layer is composed of a photopolymerizable resin composition containing an alkali soluble polymer, a photopolymerizable compound having an ethylenically unsaturated bond, a photopolymerization initiator and a black pigment.

(2) The photopolymerizable resin layered film according to (1), characterized in that the fluorine-containing compound is at least one selected from the group consisting of an amorphous fluorine resin, a copolymerization oligomer containing a perfluoroalkyl group-containing acrylate or methacrylate, a fluorine coating agent, a fluorine surfactant, a fluorine surface treatment agent containing an electron beam or ultraviolet light curable component and a fluorine surface treatment agent containing a thermosetting component.

(3) A method for manufacturing a photopolymerizable resin layered film according to (1), characterized in that the method comprises:

a first layering step of providing, on a supporting film, a fluorine-containing compound layer which is formed by coating 1 to 60 mm³ of a composition containing 30 to 100% by mass of a fluorine-containing compound per 1 m² of the supporting film and which has a contact angle to xylene of 20 degrees or more; and

a second layering step of providing, on the fluorine-containing compound layer, a photopolymerizable resin layer composed of a photopolymerizable resin composition containing an alkali soluble polymer, a photopolymerizable compound having an ethylenically unsaturated bond, a photopolymerization initiator and a black pigment.

(4) A method for manufacturing a photopolymerizable resin layered film according to (1), characterized in that the method comprises:

a first layering step of providing, on a first supporting film, a fluorine-containing compound layer which is formed by coating 1 to 60 mm³ of a composition containing 30 to 100% by mass of a fluorine-containing compound per 1 m² of the first supporting film and which has a contact angle to xylene of 20 degrees or more;

a second layering step of providing, on a second supporting film, a photopolymerizable resin layer composed of a photopolymerizable resin composition containing an alkali soluble polymer, a photopolymerizable compound having an ethylenically unsaturated bond, a photopolymerization initiator and a black pigment; and

a third layering step of laminating the surface of the photopolymerizable resin layer to the surface of the fluorine-containing compound layer.

(5) A method for manufacturing a substrate having a black matrix pattern, at least comprising:

a layering step of laminating a photopolymerizable resin layered film according to (1) or (2) on a substrate so that the photopolymerizable resin layer comes into contact with the substrate;

an exposure step in which the resulting laminate is irradiated on the opposite side to the substrate with actinic ray through a photomask having a black matrix pattern; and

a developing step of developing the photopolymerizable resin layer and removing an unexposed portion thereof.

(6) A method for manufacturing a substrate having a black matrix pattern, at least comprising:

a first layering step of providing, on a supporting film, a fluorine-containing compound layer which is formed by coating 1 to 60 mm³ of a composition containing 30 to 100% by mass of a fluorine-containing compound per 1 m² of the supporting film and which has a contact angle to xylene of 20 degrees or more;

a second layering step of providing, on a substrate, a photopolymerizable resin layer composed of a photopolymerizable resin composition containing an alkali soluble polymer, a photopolymerizable compound having an ethylenically unsaturated bond, a photopolymerization initiator and a black pigment;

a third layering step of laminating the surface of the photopolymerizable resin layer to the surface of the fluorine-containing compound layer, thereby preparing a photopolymerizable resin layered film according to (1) which is provided on the substrate;

an exposure step in which the resulting laminate is irradiated on the opposite side to the substrate with actinic ray through a photomask having a black matrix pattern; and

a developing step of developing the photopolymerizable resin layer and removing an unexposed portion thereof.

(7) A method for manufacturing a substrate having a black matrix pattern according to (6), characterized in that the fluorine-containing compound is at least one selected from the group consisting of an amorphous fluorine resin, a copolymerization oligomer containing a perfluoroalkyl group-containing acrylate or methacrylate, a fluorine coating agent, a fluorine surfactant, a fluorine surface treatment agent containing an electron beam or ultraviolet light curable component and a fluorine surface treatment agent containing a thermosetting component.

(8) A method for manufacturing a substrate having a black matrix pattern, at least comprising:

a first layering step of providing, on a substrate, a photopolymerizable resin layer composed of a photopolymerizable resin composition containing an alkali soluble polymer, a photopolymerizable compound having an ethylenically unsaturated bond, a photopolymerization initiator and a black pigment;

an exposure step in which the resulting laminate is irradiated on the opposite side to the substrate with actinic ray through a photomask having a black matrix pattern;

a developing step of developing the photopolymerizable resin layer and removing an unexposed portion thereof, thereby preparing a substrate having a black matrix pattern; and

a second layering step of attaching, on the black matrix pattern surface of the substrate having a black matrix pattern, a fluorine-containing compound layer side of a layered film with a fluorine-containing compound layer provided on a supporting film, which is formed by coating 1 to 60 mm³ of a composition containing 30 to 100% by mass of a fluorine-containing compound per 1 m² of the supporting film and which has a contact angle to xylene of 20 degrees or more.

(9) A method for manufacturing a substrate having a black matrix pattern according to (8), characterized in that the fluorine-containing compound is at least one selected from the group consisting of an amorphous fluorine resin, a copolymerization oligomer containing a perfluoroalkyl group-containing acrylate or methacrylate, a fluorine coating agent, a fluorine surfactant, a fluorine surface treatment agent containing an electron beam or ultraviolet light curable component and a fluorine surface treatment agent containing a thermosetting component.

(10) A method for manufacturing a color filter, characterized in that the method comprises:

a step of manufacturing a substrate having a black matrix pattern by a manufacturing method according to any one of (5) to (9); and

a printing step of printing a thermosensitive or photopolymerizable color ink on at least a part of the substrate having a black matrix pattern, which is not covered with the black matrix pattern, by an inkjet process.

### ADVANTAGES OF THE INVENTION

The present invention makes it possible to prepare a substrate having a black matrix pattern with excellent ink repellency on the top surface by an easy method with excellent pattern forming properties, which is required for manufacture of a color filter by an inkjet process. Using a substrate having a black matrix pattern manufactured according to the present invention makes it possible to produce a color filter at a high yield with avoiding mixing of color resist ink.

### BRIEF DESCRIPTION OF THE DRAWINGS

FIG. 1 is a schematic view illustrating a method of printing a color resist layer by an inkjet process.

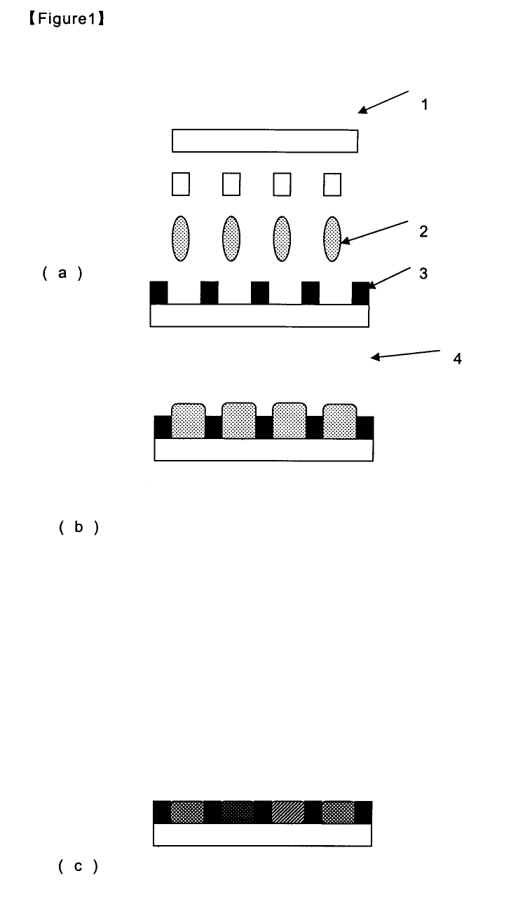

### DESCRIPTION OF SYMBOLS

1 inkjet head
2 color resist ink
3 black matrix layer
4 glass substrate

### BEST MODE FOR CARRYING OUT THE INVENTION

Hereinafter the present invention is described in detail.

(1) Photopolymerizable Resin Layered Film

A photopolymerizable resin layered film is composed of a fluorine-containing compound layer and a photopolymerizable resin layer provided on a supporting film in that order; the fluorine-containing compound layer is composed of a composition containing 30 to 100% by mass of a fluorine-containing compound and has a contact angle to xylene of 20 degrees or more, and the layer volume is 1 to 60 mm³ per 1 m²; and the photopolymerizable resin layer is composed of a photopolymerizable resin composition containing an alkali soluble polymer, a photopolymerizable compound having an ethylenically unsaturated bond, a photopolymerization initiator and a black pigment.

(a) Fluorine-Containing Compound Layer

The layer volume of the fluorine-containing compound layer is 1 to 60 mm³ per 1 m² of a supporting film. A layer volume of less than 1 mm³ is not preferable because sufficient ink repellency cannot be obtained on the surface of a black matrix pattern. It is essential that the layer volume is 60 mm³ or less in view of the ink repellency and the developability of a photopolymerizable resin when fabricating a black matrix pattern with a fluorine-containing compound layer by development after forming a fluorine-containing compound coated film on a photopolymerizable resin layer on a substrate. The layer volume is more preferably 40 mm³ or less and further preferably 12 mm³ or less in view of the influence on the glass substrate upon post-baking of a black matrix pattern with a fluorine-containing compound layer prepared by exposure and development. The above influence on the glass substrate means a small degree of ink repellency brought about on the glass substrate by heating the fluorine-containing compound component on the surface of a black matrix upon post-baking. The influence can be found by measuring the contact angle to ink on the glass substrate. The contact angle means a value measured by a contact angle meter (Model CA-VE made by Kyowa Interface Science CO. LTD.) 2 seconds after dropping 1 microliter of droplets on a sample from a microsyringe. The layer volume is more preferably 4 mm³ or less in consideration of film forming properties upon direct coating of a photopolymerizable resin layer on a fluorine-containing compound coated film.

The layer volume of the fluorine-containing compound layer is 1 to 60 mm³ per 1 m². The volume per 1 m² can be found by measuring thickness T (mm) of the fluorine-containing compound layer and calculating “thickness T (mm) of fluorine-containing compound layer”×1000 (mm)×1000 (mm)”. When the fluorine-containing compound layer is as thick as 30 nm, the thickness of the fluorine-containing compound layer can be measured, for example, from the height of the fluorine-containing compound layer provided on a flat glass substrate, using a profilometer Alfa-step manufactured by Tencor Instruments Inc. When the fluorine-containing compound layer is extremely thin, the thickness cannot be easily measured because of the accuracy of the above profilometer or the flatness of the substrate. When the fluorine-containing compound layer is extremely thin, the thickness can be calculated by separately finding the relation between the weight ratio of solid in a solution of a composition containing a fluorine-containing compound and the thickness of the fluorine-containing compound layer when the fluorine-containing compound layer is thick, and calculating based on the weight ratio of solid in the solution of the intended composition containing the fluorine-containing compound. Also, as long as the fluorine-containing compound layer has a contact angle to xylene of 20 degrees or more as described later, the layer need not be homogeneous, and may have minute pores, be meshed, or be scattered with islands of a composition containing a fluorine-containing compound. For that reason, when the layer volume of the fluorine-containing compound layer is particularly small, the amount of the fluorine-containing compound layer is not generally directly quantified based on the thickness of the fluorine-containing compound layer.

It is essential that the fluorine-containing compound layer has a contact angle to xylene of 20 degrees or more. A contact angle to xylene of 20 degrees or more is preferred because it increases the ink repellency on the surface of the black matrix. The fluorine-containing compound layer has a contact angle to xylene of more preferably 35 degrees or more, further preferably 50 degrees or more. Also, in consideration of the compatibility between the fluorine-containing compound layer and the photopolymerizable resin layer, the fluorine-containing compound layer has a contact angle to xylene of preferably 90 degrees or less, more preferably 80 degrees or less. The larger the contact angle to xylene, the better, because the ink repellency on the black matrix surface is higher when an organic compound layer containing a fluorine-containing compound is coated on the black matrix surface. The contact angle to xylene of an organic compound layer containing a fluorine-containing compound can be measured using the above-described contact angle meter (Model CA-VE made by Kyowa Interface Science CO. LTD.). Since xylene has a surface tension at 20° C. of 28.3 to 30 mN/m, which is not more than a surface tension of 50 mN/m of a solvent commonly used for ink droplets in inkjet (see JP-A-2005-352105), xylene is assumed to be the solvent in inkjet in the present invention. When water is used as the solvent for ink droplets in inkjet, the fluorine-containing compound layer has a contact angle to water of preferably 90 to 130 degrees, more preferably 100 to 120 degrees.

The fluorine-containing compound layer is composed of a composition containing 30 to 100% by mass of a fluorine-containing compound. A ratio of a fluorine-containing compound in the fluorine-containing compound layer of 30% by mass or more is preferred because the fluorine-containing compound layer has a higher contact angle to xylene, and is more preferred because the ink repellency on the black matrix surface is higher when the fluorine-containing compound layer is coated on the black matrix surface. The ratio is more preferably 50 to 100% by mass, further preferably 70 to 100% by mass. A content of a fluorine-containing compound that makes the contact angle to xylene of the fluorine-containing compound layer 20 degrees or more as described above is preferred.

In addition to the fluorine-containing compound, a plasticizer or an additive may be added to the composition that constitutes the fluorine-containing compound layer so as to improve coating properties. A curing component curable by electron beam or ultraviolet light, or a curing component curable by heat may be added to the composition that constitutes the fluorine-containing compound layer. The term “curing” herein described means increase in the molecular weight of molecules in the composition that constitutes the fluorine-containing compound layer caused by the reaction with electron beam, ultraviolet light or heat compared to the molecular weight before the reaction, or binding of a fluorine-containing compound to a reactive group in the photopolymerizable resin layer caused by the reaction with electron beam, ultraviolet light or heat.

Preferred examples of such fluorine-containing compounds include amorphous fluorine resins, copolymerization oligomers containing a perfluoroalkyl group-containing acrylate or methacrylate, fluorine coating agents, fluorine surfactants, fluorine surface treatment agents containing an electron beam or ultraviolet light curable component and fluorine surface treatment agents containing a thermosetting component. Preferred examples of copolymerization components for copolymerization oligomers containing a perfluoroalkyl group-containing acrylate or methacrylate include alkyl acrylates and alkyl methacrylates.

Specific examples are described below. Examples of amorphous fluorine resins include LUMIFLON (registered trademark) and CYTOP (registered trademark) manufactured by Asahi Glass Co., Ltd. Examples of copolymerization oligomers containing a perfluoroalkyl group-containing (meth)acrylate and an alkyl (meth)acrylate as main components include MODIPER (registered trademark) F SERIES manufactured by NOF Corporation, UNIDYNE (registered trademark) manufactured by DAIKIN INDUSTRIES, LTD. and MEGAFACE (registered trademark) F470, F480 and F110 SERIES manufactured by Dainippon Ink & Chemicals Incorporated. For copolymerization, block copolymerization is more preferred. Examples of fluorine coating agents include Novec (registered trademark) EGC 1700 manufactured by Sumitomo 3M Ltd. Examples of fluorine surfactants include MEGAFACE (registered trademark) F114, F410, 440, 450 and 490 SERIES manufactured by Dainippon Ink & Chemicals Incorporated. Examples of fluorine surface treatment agents containing an electron beam or ultraviolet light curable component include PolyFox PF-3320 manufactured by OMNOVA Solutions, Inc. and CHEMINOX (registered trademark) FAMAC-8 manufactured by UNIMATEC CO., LTD. Examples of fluorine surface treatment agents containing a thermosetting component include Novec (registered trademark) EGC1720 manufactured by Sumitomo 3M Ltd. and DICGUARD (registered trademark) NH-10 and NH-15 manufactured by Dainippon Ink & Chemicals Incorporated. The fluorine-containing compound in the fluorine-containing compound layer may be a mixture of multiple kinds of fluorine-containing compounds.

In consideration of the light transmittance of the fluorine-containing compound layer, amorphous fluorine resins are preferred because they have high ultraviolet transmittance due to their amorphousness (reference: Reports of the Research Laboratory, Vol. 55, 2005, Asahi Glass Co., Ltd.). When an ink repellent layer is provided on the surface of a photopolymerizable resin, a fluorine-containing compound containing an ethylenically unsaturated bond is preferred because the photopolymerizable resin and the ink repellent agent can be easily bound to each other upon exposure.

(b) Supporting Film

Although the thickness or transparency of a supporting film need not be considered as long as the supporting film is removed when performing an exposure step, the flatter the supporting film, the better. When performing an exposure step of irradiation of active light through a supporting film, preferably the supporting film has a thickness of 5 to 40 μm and is transparent.

Transparent organic polymer films that substantially transmit active light are preferred as a supporting film, and examples thereof include polyethylene terephthalate films, polyvinyl alcohol films, polyvinyl chloride films, vinyl chloride copolymer films, polyvinylidene chloride films, vinylidene chloride copolymer films, methyl methacrylate copolymer films, polystyrene films, polyacrylonitrile films, styrene copolymer films, polyamide films, cellulose derivative films, triacetyl cellulose films and polypropylene films. Those films stretched according to need can also be used.

Organic polymer films having a haze of 5.0 or less are preferred. The haze herein described means a value of turbidity calculated by means of haze value H=D/T×100 from total transmittance T of light irradiated from a lamp and transmitted through a sample and transmittance D of light diffused and scattered in the sample. These matters are prescribed in JIS-K-7105 and measurement can be easily performed by a commercially available turbidimeter.

(c) Method of Forming Fluorine-Containing Compound Layer on Supporting Film

Examples of methods of forming a fluorine-containing compound layer on a supporting film include those in which a composition containing a fluorine-containing compound is coated on a supporting film by a known coating method such as dip coating, Mayer bar coating, gravure coating, doctor coating, air knife coating, bar coating, comma coating or die coating, followed by drying or curing by a known method suitable for the fluorine-containing compound layer, such as heating treatment or ultraviolet irradiation. Also, as long as the fluorine-containing compound layer has a contact angle to xylene of 20 degrees or more as described above, the layer need not be homogeneous, and may have minute pores, be meshed, or be scattered with islands of a composition containing a fluorine-containing compound. Hereinafter a film in which a fluorine-containing compound layer is formed on a supporting film is referred to as a fluorine-containing compound coated film.

A functional layer such as a layer with high oxygen barrier effect or a cushioning layer may be disposed between the supporting film and the fluorine-containing compound layer. Known materials with low oxygen permeability can be used as the layer with high oxygen barrier effect, and examples thereof include those described as an intermediate layer in [0033] of JP-A-10-039133. Polyvinyl alcohol, derivatives thereof, polyvinyl pyrrolidone, derivatives thereof and mixtures thereof are preferred. The layer has a thickness of preferably 0.1 to 5 μm. Examples of cushion layers include those described as alkali soluble thermoplastic resins in [0032] of JP-A-10-039133, and alkali soluble thermoplastic resins having a softening point of 80° C. or lower are particularly preferred. The layer has a thickness of preferably 5 μm to 30 μm.

(d) Photopolymerizable Resin Layer

A photopolymerizable resin layer is prepared by applying a liquid photopolymerizable resin composition to a supporting film or a fluorine-containing compound layer formed on a supporting film, and subsequently drying the same. The liquid photopolymerizable resin composition may contain an alkali soluble polymer, a photopolymerizable compound having an ethylenically unsaturated bond, a photopolymerization initiator and a black pigment. Also, a commercially available black resist or black color resist may be used. A liquid photopolymerizable resin composition which is not ink repellent when formed into a photopolymerizable resin layer is preferred.

Examples of commercially available black resist and black color resist include black resist CFPR-BK5000 series, 8300 series, 8400 series and 8800 series manufactured by TOKYO OHKA KOGYO CO. LTD., alkaline developable black resist NSBK series, V-259BK and V-259BKIS series manufactured by Nippon Steel Chemical Co., Ltd. and COLOR MOSAIC (registered trademark) CK series manufactured by FUJIFILM Electronic Materials Co., Ltd.

A photopolymerizable resin composition prepared by mixing an alkali soluble polymer, a photopolymerizable monomer having an ethylenic double bond, a black pigment, a photopolymerization initiator, a solvent and various additives is described below.

Preferably, the alkali soluble polymer is prepared by copolymerizing a monomer having a carboxyl group in the side chain and a (meth)acrylic monomer. The term (meth)acryl herein described means acryl or methacryl.

Examples of monomers having a carboxyl group in the side chain include (meth)acrylic acid, fumaric acid, cinnamic acid, crotonic acid, itaconic acid, citraconic acid, maleic anhydride and maleic acid half ester. In the alkali soluble polymer, the ratio of copolymerization of a monomer having a carboxyl group in the side chain is preferably 5% by mass or more in consideration of developability, and 30% by mass or less in consideration of the dispersibility of black pigment and the suppression of attachment of black pigment on the substrate after development. The monomer is copolymerized in a ratio of more preferably 5% by mass to 20% by mass.

Examples of (meth)acrylic monomers include alkyl (meth)acrylates such as benzyl (meth)acrylate, methyl (meth)acrylate, ethyl (meth)acrylate, n-butyl (meth)acrylate, iso-butyl (meth)acrylate, sec-butyl (meth)acrylate, tert-butyl (meth)acrylate, 2-ethylhexyl (meth)acrylate and benzyl (meth)acrylate, (meth)acrylates having a hydroxyl group in the side chain such as 2-hydroxyethyl (meth)acrylate, 2-hydroxypropyl (meth)acrylate and glycidyl mono(meth)acrylate, (meth)acrylates having an alicyclic side chain such as cyclohexyl (meth)acrylate, isobornyl (meth)acrylate, dicyclopentanyl (meth)acrylate, dicyclopentadienyl (meth)acrylate and adamantyl (meth)acrylate, and (meth)acrylamide, (meth)acrylonitrile, phenyl (meth)acrylate and glycidyl (meth)acrylate.

The term (meth)acrylate herein described means acrylate or methacrylate.

In a preferred embodiment of the present invention, styrene may be copolymerized as a monomer in addition to the above copolymerization components.

In consideration of the heat resistance and the flatness of black matrix patterns, a copolymer of styrene, methyl methacrylate and methacrylic acid, containing 20 to 30% by mass of styrene, 40 to 60% by mass of methyl methacrylate and 20 to 30% by mass of methacrylic acid is preferred. Also, in consideration of the developability of the photopolymerizable resin layer, a copolymer of benzyl methacrylate and methacrylic acid, containing 75 to 85% by mass of benzyl methacrylate and 15 to 25% by mass of methacrylic acid is preferred.

The alkali soluble polymer has a weight average molecular weight of preferably 3,000 to 50,000. The molecular weight is preferably 50,000 or less in consideration of developability and 3,000 or more in consideration of adhesion properties. The weight average molecular weight is more preferably 10,000 to 40,000. The molecular weight is measured as a weight average molecular weight (on a basis of polystyrene) using gel permeation chromatography (GPC) manufactured by JASCO Corporation (pump: Gulliver, PU-1580 type, column: Shodex (registered trademark) manufactured by SHOWA DENKO K.K. (KF-807, KF-806M, KF-806M, KF-802.5) four columns in series, mobile phase solvent: tetrahydrofuran, using calibration curve based on a polystyrene standard sample (standard sample Shodex STANDARD, SM-105 polystyrene manufactured by SHOWA DENKO K.K.)).

The alkali soluble polymer has a carboxyl group content of preferably 200 to 2,000 in terms of acid equivalent. The acid equivalent means the mass of a linear polymer containing 1 equivalent of carboxyl groups. The acid equivalent is preferably 2,000 or less in consideration of developability and 200 or more in consideration of the suppression of attachment of black pigment on the substrate after development. The acid equivalent is more preferably 400 to 900, and further preferably 500 to 800. The acid equivalent is measured by a potentiometric titration method using 0.1 mol/L sodium hydroxide with Hiranuma Automatic Titrator (COM-555) manufactured by Hiranuma Sangyo Co., Ltd.

Preferably, an alkali soluble polymer is synthesized by adding an appropriate amount of a radical polymerization initiator such as benzoyl peroxide or azobisisobutyronitrile to a solution of a mixture of the above various monomers, which is diluted with a solvent such as acetone, methyl ethyl ketone or isopropanol, and stirring with heating. An alkali soluble polymer may also be synthesized by adding dropwise part of a mixture to a reaction solution. After completion of the reaction, a solvent may be further added to the resultant to adjust to the desired concentration. For the synthetic method, bulk polymerization, suspension polymerization or emulsion polymerization may be employed in addition to solution polymerization.

Also, as an alkali soluble polymer, an epoxy acrylate resin synthesized by adding α,β-unsaturated monocarboxylic acid or α,β-unsaturated monocarboxylic acid ester containing a carboxyl group in the ester moiety to an epoxy resin and further allowing to react with polybasic acid anhydride as described in the specification of JP-B-3754065, or a photopolymerizable unsaturated compound prepared by allowing a reactant of bisphenol fluorene epoxy acrylate and tetracarboxylic dianhydride to react with phthalic anhydride as described in claim 1 of JP-B-3268771 may be used.

Examples of photopolymerizable compounds having an ethylenically unsaturated double bond include succinic acid-modified pentaerythritol tri(meth)acrylate, phthalic acid-modified pentaerythritol tri(meth)acrylate, isophthalic acid-modified pentaerythritol tri(meth)acrylate, terephthalic acid-modified pentaerythritol tri(meth)acrylate, polyalkylene glycol dimethacrylate prepared by adding an average of 2 moles of propylene oxide and an average of 6 moles of ethylene oxide to each end of bisphenol A, polyethylene glycol dimethacrylate prepared by adding an average of 5 moles of ethylene oxide to each end of bisphenol A (NK ESTER BPE-500 manufactured by SHIN-NAKAMURA CHEMICAL CO., LTD.), 1,6-hexanediol di(meth)acrylate, 1,4-cyclohexanediol di(meth)acrylate, polypropylene glycol di(meth)acrylate, polyethylene glycol di(meth)acrylate, 2-di(p-hydroxyphenyl)propane di(meth)acrylate, glycerol tri(meth)acrylate, trimethylolpropane tri(meth)acrylate, polyoxypropyl trimethylolpropane tri(meth)acrylate, polyoxyethyl trimethylolpropane triacrylate, pentaerythritol tetra(meth)acrylate, dipentaerythritol penta(meth)acrylate, trimethylolpropane triglycidyl ether tri(meth)acrylate, bisphenol A diglycidyl ether di(meth)acrylate, β-hydroxypropyl-β′-(acryloyloxy)propyl phthalate, phenoxy polyethylene glycol (meth)acrylate, nonylphenoxy polyethylene glycol (meth)acrylate, nonylphenoxy polyalkylene glycol (meth)acrylate and polypropylene glycol mono(meth)acrylate.

The photopolymerization initiator is preferably an oxime ester compound. Examples thereof include oxime esters such as 1-phenyl-1,2-propanedione-2-O-benzoyl oxime and 1-phenyl-1,2-propanedione-2-(O-ethoxycarbonyl)oxime and compounds described JP-A-2004-534797. In particular, ethanone, 1-[9-ethyl-6-(2-methylbenzoyl)-9H-carbazol-3-yl]-,1-(O-acetyloxime) (IRGACURE OXE-02 manufactured by Ciba Specialty Chemicals) is preferred.

The photopolymerizable resin composition may contain a photopolymerization initiator other than oxime ester compounds, a sensitizer or a chain transfer agent. Examples of photopolymerization initiators include thioxanthone, 2,4-diethyl thioxanthone, isopropyl thioxanthone, 2-chlorothioxanthone, and 2,4,5-triarylimidazole dimers such as 2-(o-chlorophenyl)-4,5-diphenyl imidazole dimer, 2-(o-chlorophenyl)-4,5-bis-(m-methoxyphenyl)imidazole dimer and 2-(p-methoxyphenyl)-4,5-diphenyl imidazole dimer. Examples thereof also include p-aminophenyl ketones such as p-aminobenzophenone, p-butylaminobenzophenone, p-dimethylaminoacetophenone, p-dimethylaminobenzophenone, p,p′-bis(ethylamino)benzophenone, p,p′-bis(dimethylamino)benzophenone [Michler's ketone], p,p′-bis(diethylamino)benzophenone and p,p′-bis(dibutylamino)benzophenone. Examples thereof also include various known compounds including quinones such as 2-ethyl anthraquinone and 2-tert-butyl anthraquinone, aromatic ketones such as benzophenone, benzoins, benzoin ethers such as benzoin methyl ether and benzoin ethyl ether, acridine compounds such as 9-phenylacridine, triazine compounds such as 2,4,6-trichloro-s-triazine, 2-phenyl-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-piperonyl-4,6-bis(trichloromethyl)-s-triazine, 2,4-bis(trichloromethyl)-6-styryl-s-triazine, 2-(naphth-1-yl)-4,6-bis(trichloromethyl)-s-triazine, 2-(4-methoxy-naphth-1-yl)-4,6-bis(trichloromethyl)-s-triazine, 2,4-trichloromethyl-(piperonyl)-6-triazine and 2,4-trichloromethyl (4′-methoxystyryl)-6-triazine, benzyl dimethylketal, benzyl diethylketal, 2-benzyl-dimethylamino-1-(4-morpholinophenyl)-butanone-1, bis(2,4,6-trimethylbenzoyl)-phenyl phosphineoxide and 2-methyl-2-morpholino-1-(4-(methylthiophenyl)-propan-1-one.

Examples of sensitizers and chain transfer agents include various known compounds including N-arylglycines and polyfunctional thiols such as mercaptotriazole derivatives, mercaptotetrazole derivatives, mercaptothiadiazole derivatives, hexanedithiol, decanedithiol, 1,4-butanediol bisthiopropionate, 1,4-butanediol bisthioglycolate, ethylene glycol bisthioglycolate, ethylene glycol bisthiopropionate, trimethylolpropane tristhioglycolate, trimethylolpropane tristhiopropionate, trimethylolpropane tris(3-mercaptobutyrate), pentaerythritol tetrakisthioglycolate, pentaerythritol tetrakisthiopropionate, trimercaptopropionic acid tris(2-hydroxyethyl)isocyanurate, 1,4-dimethylmercaptobenzene, 2,4,6-trimercapto-s-triazine and 2-(N,N-dibutylamino)-4,6-dimercapto-s-triazine.

As a black pigment, either an organic or an inorganic pigment may be used and known various pigments may be used. Examples of organic pigments include C.I. pigment black 1, C.I. pigment black 7 and C.I. pigment black 31, and examples of inorganic pigments include carbon black, titanium black, titanium oxynitride, black low-dimensional titanium oxide, graphite powder, iron black and copper oxide. In addition, inorganic pigments including oxide, complex oxide, sulfide, sulfate or carbonate of metal such as Cu, Fe, Mn, Cr, Co, Ni, V, Zn, Se, Mg, Ca, Sr, Ba, Pd, Ag, Cd, In, Sn, Sb, Hg, Pb, Bi, Si and Al may be used. Carbon black is preferred in consideration of the light shielding effect and the influence on the sensitivity, resolution and adhesion properties of black matrix. Titanium black is preferred in consideration of the insulation properties of black matrix. Carbon black has a primary particle size of preferably 20 to 60 nm, more preferably 30 to 45 nm in consideration of ultraviolet transmittance and the dispersibility of pigment. The dispersion particle size is preferably 100 to 250 nm, more preferably 150 to 200 nm in consideration of ultraviolet transmittance and the dispersibility of pigment.

The photopolymerizable resin composition may be made substantially black by mixing pigments of multiple colors including red, blue and green.

The preferable contents of the alkali soluble polymer, the photopolymerizable compound having an ethylenic double bond, the photopolymerization initiator and the black pigment in the photopolymerizable resin composition are as follows. The content of the alkali soluble polymer is preferably 5% by mass to 50% by mass, more preferably 10% by mass to 40% by mass. The content of the photopolymerizable compound having an ethylenic double bond is preferably 5% by mass to 50% by mass, more preferably 10% by mass to 40% by mass. The content of the photopolymerization initiator is preferably 0.1% by mass to 20% by mass, more preferably 1% by mass to 10% by mass. The content of the black pigment is preferably 10% by mass to 70% by mass, more preferably 20% by mass to 60% by mass.

The photopolymerizable resin composition may contain a dispersant. The black pigment may be previously dispersed in a solvent with a dispersant.

Examples of dispersants include polyurethane, carboxylic acid esters such as polyacrylate, unsaturated polyamides, (partial) amine salts of polycarboxylic acids, ammonium salts of polycarboxylic acids, alkylamine salts of polycarboxylic acids, polysiloxanes, hydroxyl group containing polycarboxylic acid esters, modified products thereof, amides formed by the reaction between poly(lower alkyleneimine) and polyester having a free carboxyl group and salts thereof. The alkali soluble polymers used in the present invention, the above-described alkali soluble polymers in which benzyl (meth)acrylate is copolymerized, and other alkali soluble polymers may also be used as a pigment dispersant. Furthermore, anionic active agents such as polycarboxylic acid type polymer active agents and polysulfonic acid type polymer active agents, and nonionic active agents such as polyoxyethylene and polyoxylene block polymers may be used as a dispersant aid with a dispersant.

Also, the surface of a black pigment, in particular, carbon black, may be covered with a resin or modified by a resin or a low molecular weight compound in consideration of the dispersibility and insulation properties. Examples of resins used for surface modification include polymers containing a functional group reactive with a carboxyl group on the surface of carbon black, such as polycarbodiimide and epoxy resin. Also, examples of low molecular weight compounds include substituted benzenediazonium compounds. For the method of covering and modification with resin, the dispersants and the methods described in JP-A-2004-219978, JP-A-2004-217885, JP-A-2004-360723, JP-A-2003-201381, JP-A-2004-292672, JP-A-2004-29745, JP-A-2005-93965, JP-A-2004-4762, U.S. Pat. No. 5,554,739 and U.S. Pat. No. 5,922,118 may be used.

The photopolymerizable resin composition may contain a plasticizer if necessary. Examples of such a plasticizer include phthalic acid esters such as diethyl phthalate, p-toluenesulfonamide, polypropylene glycol, polyethylene glycol monoalkyl ether and polyalkylene oxide modified bisphenol A derivatives such as an ethylene oxide adduct or propylene oxide adduct of bisphenol A.

The photopolymerizable resin composition may contain a coupler component such as a silane coupling agent or a titanium coupling agent if necessary.

(e) Method of Forming Photopolymerizable Resin Layer on Fluorine-Containing Compound Layer

When applying a photopolymerizable resin composition in the form of a liquid photopolymerizable resin composition to the fluorine-containing compound layer formed on a supporting film, a solvent is added to the composition so as to set to the best condition for the application.

Examples of solvents include ethylene glycol monomethyl ether, ethylene glycol monoethyl ether, ethylene glycol monopropyl ether, ethylene glycol monobutyl ether, ethylene glycol dimethyl ether, ethylene glycol diethyl ether, ethylene glycol dipropyl ether, propylene glycol monomethyl ether, propylene glycol monoethyl ether, propylene glycol monopropyl ether, propylene glycol monobutyl ether, propylene glycol dimethyl ether, propylene glycol diethyl ether, diethylene glycol monomethyl ether, diethylene glycol monoethyl ether, diethylene glycol dimethyl ether, diethylene glycol diethyl ether, ethylene glycol monomethyl ether acetate, ethylene glycol monoethyl ether acetate, ethylene glycol monopropyl ether acetate, ethylene glycol monobutyl ether acetate, propylene glycol monomethyl ether acetate (PGMEA), propylene glycol monoethyl ether acetate, propylene glycol monopropyl ether acetate, 2-methoxybutyl acetate, 3-methoxybutyl acetate, 4-methoxybutyl acetate, 2-methyl-3-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, acetone, methyl ethyl ketone, diethyl ketone, methyl isobutyl ketone, ethyl isobutyl ketone, methyl carbonate, ethyl carbonate, propyl carbonate, butyl carbonate, benzene, toluene, xylene, cyclohexanone, methanol, ethanol, propanol, butanol, hexanol, cyclohexanol, ethylene glycol, diethylene glycol and glycerol.

Methyl ethyl ketone and methyl isobutyl ketone are preferred in consideration of toxicity and drying properties in coating on the fluorine-containing compound coated film or a supporting film. Propylene glycol monomethyl ether acetate (PGMEA) is preferred in consideration of the dispersion stability of coloring pigment, in particular, black pigment and the solubility of the alkali soluble polymer. To satisfy both of the above properties, methyl ethyl ketone or methyl isobutyl ketone and PGMEA may be mixed at an appropriate ratio. For example, black pigment is previously dispersed in PGMEA and an alkali soluble polymer is previously dispersed in PGMEA; the two solutions, an alkali soluble polymer prepared by copolymerizing benzyl (meth)acrylate, a photopolymerizable compound having an ethylenically unsaturated double bond, a photopolymerization initiator and other various additives are mixed; and the resultant is appropriately diluted with a solvent such as methyl ethyl ketone or PGMEA, whereby a solution of a photopolymerizable resin composition which shows good coatability and drying properties on the fluorine-containing compound layer is prepared.

Examples of methods of applying a liquid photopolymerizable resin composition to a supporting film or a fluorine-containing compound layer include known coating methods such as Mayer bar coating, gravure coating, doctor coating, air knife coating, bar coating, comma coating and die coating. Examples of methods of drying include means such as hot plates and ovens. These methods are not particularly limited.

(f) Protective Layer

In a photopolymerizable resin layered film, a protective layer may be provided on the surface of a photopolymerizable resin layer which is on the opposite side from the supporting film if necessary. Preferably, the adhesion between the protective layer and the photopolymerizable resin layer is sufficiently smaller than the adhesion between the supporting film and the photopolymerizable resin layer, enabling easy peeling.

Examples of such a protective layer include polyethylene films, polyethylene terephthalate films, polypropylene films, stretched polypropylene films (e.g., E-200C manufactured by Oji Paper Co., Ltd.) and release-treated polyethylene terephthalate films. The protective layer has a thickness of preferably 5 to 38 μm, more preferably 10 to 25 μm in consideration of handling.

(g) Method for Manufacturing Photopolymerizable Resin Layered Film

Preferably, the photopolymerizable resin layered film is manufactured by either of the following methods.

### <Direct Coating Method>

A manufacturing method including a first layering step of providing a fluorine-containing compound layer on a supporting film and a second layering step of providing a photopolymerizable resin layer composed of a photopolymerizable resin composition containing an alkali soluble polymer, a photopolymerizable compound having an ethylenically unsaturated bond, a photopolymerization initiator and a black pigment on the fluorine-containing compound layer.

### <Lamination Method>

A manufacturing method including a first layering step of providing a fluorine-containing compound layer on a first supporting film, a second layering step of providing a photopolymerizable resin layer composed of a photopolymerizable resin composition containing an alkali soluble polymer, a photopolymerizable compound having an ethylenically unsaturated bond, a photopolymerization initiator and a black pigment on a second supporting film, and a third layering step of laminating the surface of the photopolymerizable resin layer to the surface of the fluorine-containing compound layer.

The photopolymerizable resin layered film can be prepared by the following method. As a photopolymerizable resin composition, a liquid photopolymerizable resin composition is prepared by mixing an alkali soluble polymer, a photopolymerizable compound having an ethylenically unsaturated double bond, a photopolymerization initiator, a black pigment and a solvent; a photopolymerizable resin layer is formed by applying the liquid photopolymerizable resin composition to a fluorine-containing compound coated film and subsequently drying the same; and then a polyethylene film which is a protective layer is laminated. The photopolymerizable resin layer has a thickness of preferably 0.3 μm or more in consideration of the light shielding effect of black matrix and the accuracy of film thickness upon application, and particularly preferably 1.0 μm or more in consideration of preventing mixing of colors with neighboring pixels when forming color pixels by inkjet. Also, the photopolymerizable resin layer has a thickness of preferably 4.5 μm or less in consideration of the flatness when used in a color filter. When manufacturing a color filter using resin black matrix, irregularities on the surface of the color filter disturbs alignment of liquid crystal if the black matrix has an increased height, and so in some cases a flattening film called an overcoat layer is formed or polishing is performed so as to flatten the surface. The black matrix has a height of preferably 4.5 μm or less as the influence on the alignment of liquid crystal can be reduced, the thickness of the overcoat layer can be reduced, or the entire thickness of the color filter can be reduced. The black matrix has a height of more preferably 1.0 to 3.0 μm, further preferably 1.5 to 2.5 μm in consideration of the optimum film thickness of color pixels estimated from the relationship between the solid content of ink and the light transmittance of color pixels when forming color pixels by inkjet.

(2) Method for Manufacturing Substrate Having Black Matrix Pattern

In a substrate having a black matrix pattern, the substrate is preferably transparent. Transparent substrates are not limited as long as they are used in a color filter of a liquid crystal display, and specific examples thereof include alkali-free glass substrates, transparent plastic substrates and transparent plastic films. The substrate has a thickness of preferably 100 to 1000 μm in consideration of the strength of a liquid crystal display.

Preferably, the substrate having a black matrix pattern is manufactured by any of the following methods.

### <Photopolymerizable Resin Layered Film Method>

A method for manufacturing a substrate having a black matrix pattern including a layering step of providing the above-described photopolymerizable resin layered film on a substrate so that the photopolymerizable resin layer comes into contact with the substrate, a peeling step of peeling off a supporting film according to need, an exposure step in which the resulting laminate is irradiated on the opposite side to the substrate with actinic ray through a photomask having a black matrix pattern, a peeling step of peeling off a supporting film if any and a developing step of developing the photopolymerizable resin layer and removing an unexposed portion thereof.

### <Post Lamination Method>

A method for manufacturing a substrate having a black matrix pattern including a first layering step of providing a fluorine-containing compound layer on a supporting film, a second layering step of providing a photopolymerizable resin layer on a substrate and a third layering step of laminating the surface of the photopolymerizable resin layer to the surface of the fluorine-containing compound layer, thereby preparing a photopolymerizable resin layered film provided on the substrate, a peeling step of peeling off the supporting film according to need, an exposure step in which the resulting laminate is irradiated on the opposite side to the substrate with actinic ray through a photomask having a black matrix pattern, a peeling step of peeling off a supporting film if any and a developing step of developing the photopolymerizable resin layer and removing an unexposed portion thereof.

<Method of Lamination onto Pattern>

A method for manufacturing a substrate having a black matrix pattern including a first layering step of providing a photopolymerizable resin layer on a substrate, an exposure step in which the resulting laminate is irradiated on the opposite side to the substrate with actinic ray through a photomask having a black matrix pattern, a developing step of developing the photopolymerizable resin layer and removing an unexposed portion thereof, thereby preparing a substrate having a black matrix pattern, a second layering step of attaching, on the black matrix pattern surface of the substrate having a black matrix pattern, a fluorine-containing compound layer side of a layered film with a fluorine-containing compound layer provided on a supporting film, and a peeling step of peeling off the supporting film.

First, a method including preparing a photopolymerizable resin layered film by the above-described <Direct coating method> and manufacturing a substrate having a black matrix pattern by the above-described <Photopolymerizable resin layered film method> is described.

First, after removing the protective layer, the above-described photopolymerizable resin layered film is laminated on a glass substrate (thermocompression bonding). At that stage, the glass substrate is preferably pre-heated. The glass substrate is pre-heated to preferably 100° C. or higher in consideration of good lamination and avoidance of air from being included upon lamination to provide sufficient adhesion, and preferably 150° C. or lower in consideration of the heat resistance of the supporting film. The temperature is more preferably 110° C. or higher and 140° C. or lower.

Next, the resulting laminate is irradiated on the opposite side to the substrate with actinic ray through a photomask having a black matrix pattern. When irradiating the opposite side of the substrate, a photopolymerizable resin layer may be exposed through a photomask having a black matrix pattern and further through a supporting film, or exposed through a photomask having a black matrix pattern after removing such a supporting film. When exposing with an increased exposure, the supporting film may be peeled off before exposure. However, when exposing after removing the supporting film, preferably high sensitivity is set by appropriately adjusting the mixing amount of initiators and photopolymerizable monomers. The supporting film has a significant effect on the sensitivity, and so it is preferred that much higher sensitivity is set compared to exposure through a supporting film.

Next, a supporting film is accordingly removed if any, and unexposed portions of the photopolymerizable resin layer are developed and removed using an aqueous alkaline solution. An aqueous sodium carbonate solution, an aqueous potassium carbonate solution, an aqueous potassium hydroxide solution, a mixed aqueous solution of sodium hydrogen carbonate and sodium carbonate, or an aqueous solution of organic amine such as tetramethylammonium hydroxide is used as an aqueous alkaline solution. Such aqueous alkaline solutions are selected depending on the properties of the photopolymerizable resin layer, and generally a 0.1 to 3% by mass aqueous sodium carbonate solution or a 0.03 to 0.1% by mass aqueous potassium hydroxide solution is used. To remove undeveloped remaining portions of the photopolymerizable resin layer, according to need, the layer may be further developed with a different developer. Such a different developer may be an aqueous alkaline solution of a different kind from that of the first developer used for developing the photopolymerizable resin layer, an acidic developer or a developer containing an organic solvent. The composition of the photopolymerizable resin layer may be selected depending on developers. Also, undeveloped remaining portions of the photopolymerizable resin layer, coloring pigment or black pigment may be physically removed by means of high pressure water washing or the like. A water pressure of 0.2 MPa or more is effective.

After the developing step, preferably a post-baking step is performed.

The post-baking step facilitates curing of the photopolymerizable resin layer which has not been completely cured in the exposure step by heating a substrate having a black matrix pattern after developing or irradiating the substrate with infrared rays. The temperature and the time in the post-baking step depends on the thickness or the composition of the photopolymerizable resin layer. The temperature is preferably 150° C. to 250° C. and the time is preferably 5 to 90 minutes in consideration of sufficient chemical resistance, ink resistance, alkali resistance and increase in optical density per film thickness due to shrinkage. Known apparatus such as drying ovens, electric furnaces and infrared furnaces may be used.

Also, before the post-baking step, an additional exposure step (post-exposure step) may be added. The post-exposure step facilitates curing of the photopolymerizable resin layer by subjecting a substrate having a black matrix pattern with a water repellent surface after development to exposure from the photopolymerizable resin layer surface or the glass substrate surface. The exposure is preferably 100 to 5000 mJ/cm² in consideration of the productivity.

Second, a method including preparing a photopolymerizable resin layered film by the above-described <Lamination method> and manufacturing a substrate having a black matrix pattern by the above-described <Photopolymerizable resin layered film method> is described.

This method differs from the <Direct coating method> in that, in the method for preparing a photopolymerizable resin layered film, a photopolymerizable resin layered film is prepared by laminating a photopolymerizable resin layer prepared by coating a photopolymerizable resin composition on another supporting film 2 and subsequent drying thereof to a fluorine-containing compound layer on a supporting film, not by coating a liquid photopolymerizable resin composition on the fluorine-containing compound layer surface provided on a supporting film and subsequently drying the same. When manufacturing a substrate having a black matrix pattern using the photopolymerizable resin layer, a substrate having a black matrix pattern can be manufactured in the same manner as in the <Direct coating method> with assuming that the supporting film 2 on the photopolymerizable resin layer side corresponds to the protective layer in the <Direct coating method> and peeling off the supporting film 2.

The flatter the supporting film 2 in the present invention, the better. The same supporting film as that used for preparing the above-described fluorine-containing compound coated film may be used. In the method for manufacturing a substrate having a black matrix pattern by the <Lamination method>, the substrate can be manufactured in the same manner as in the <Direct coating method> except that, when a photopolymerizable resin layer is provided on a supporting film 2, the film on which a photopolymerizable resin layer is provided is not a fluorine-containing compound coated film but a supporting film 2.

Means for laminating the photopolymerizable resin layer surface to the fluorine-containing compound layer surface includes cold lamination, lamination with heating and vacuum lamination. The speed of lamination is preferably 1 to 100 m/minute in consideration of productivity. As the supporting film 2 on the photopolymerizable resin layer side is regarded as a protective layer and peeled off for use, preferably the peeling force between the photopolymerizable resin layer and the supporting film 2 is smaller than the peeling force between a fluorine-containing compound layer and a supporting film in a fluorine-containing compound coated film. The peeling force herein described can be measured by 180 degree peel strength test in accordance with JIS Z 0237. When there is no difference between the two, the supporting film 2 can be easily peeled off by maintaining the peeling angle between the supporting film 2 and the photopolymerizable resin layered film at 90 degrees or more on the supporting film side and at nearly 0 degree on the photopolymerizable resin layered film side.

The photopolymerizable resin layered film according to the <Lamination method> can be manufactured in the same manner as in the <Direct coating method> except for the above.

The substrate having black matrix according to the <Lamination method> can be manufactured in the same manner as in the above <Direct coating method> using the above photopolymerizable resin layered film.

Third, a method for manufacturing a substrate having a black matrix pattern by the above-described <Post lamination method> is described.

This invention differs from the <Photopolymerizable resin layered film method> in that the layering step includes previously forming a photopolymerizable resin layer on a substrate and then laminating the surface of the photopolymerizable resin layer to the surface of the fluorine-containing compound layer, compared to the <Photopolymerizable resin layered film method> in which a photopolymerizable resin layered film is prepared by providing a photopolymerizable resin layer on a fluorine-containing compound layer and the photopolymerizable resin layered film is then provided on a glass substrate.

The photopolymerizable resin layer provided on a substrate in this invention is formed by a method of applying a liquid photopolymerizable resin composition to a substrate and subsequently drying the same or a method of thermally transferring a photopolymerizable resin layer separately formed on a supporting film 2 to a substrate by a laminator as described in the <Lamination method>.

As the liquid photopolymerizable resin composition, those described in the <Direct coating method> may be used. Examples of methods of applying the above-described liquid photopolymerizable resin to a substrate include, but are not particularly limited to, spin coating, roll coating, bar coating, dip coating and spray coating. Examples of methods of drying and forming a film of a photopolymerizable resin composition solution on a substrate include, but are not particularly limited to, means such as hot plates and ovens.

The method for manufacturing a substrate having a black matrix pattern includes a step of providing the surface of the above-described fluorine-containing compound layer on a supporting film to the surface of the photopolymerizable resin layer formed on a substrate. The layering step is performed by lamination (thermocompression bonding). At that stage, the substrate is preferably previously heated to 60 to 120° C. in consideration of increasing the adhesion properties between the photopolymerizable resin layer surface and the fluorine-containing compound layer. Examples of heating means include heating by a hot plate, heating by a hot air dryer, heating by infrared rays, heating by ultrasonic waves, heating by electromagnetic induction, warming in a pressure oven, warming in a vacuum container and lamination using a heating roll. Of these, one or more means selected from heating by a hot plate, heating by a hot air dryer, heating by infrared rays and lamination using a heating roll is preferred. The temperature of the lamination roll upon lamination (thermocompression bonding) is preferably 40° C. to 130° C.; the transfer speed of the substrate is preferably 0.2 m to 4 m per minute; and the pressure of the lamination roll is preferably 0.05 MPa to 1 MPa. Also, using a vacuum laminator or wet lamination upon lamination is preferred because such means has an effect of removing the air between the fluorine-containing compound layer and the photopolymerizable resin layer formed on a substrate and increasing the sensitivity of the photopolymerizable resin layer. After the layering step, a heating step, an exposure step, a developing step, a post-exposure step and a post-baking step are each carried out in the same manner as in the <Direct coating method>, whereby a substrate having a black matrix pattern is prepared.

Fourth, a method for manufacturing a substrate having a black matrix pattern by the above-described <Lamination onto pattern method> is described.

This manufacturing method differs from the <Post lamination method> in that a fluorine-containing compound layer is laminated on a black matrix pattern surface which has been formed on a substrate, compared to the <Post lamination method> in which the surface of a photopolymerizable resin layer of a photopolymerizable resin layered film previously formed on a substrate and the surface of a fluorine-containing compound layer are laminated, followed by exposure and development to form a pattern.

A substrate having a black matrix pattern is prepared through, in sequence, at least a step of providing a photopolymerizable resin layer composed of a photopolymerizable resin composition containing an alkali soluble polymer, a photopolymerizable compound having an ethylenically unsaturated bond, a photopolymerization initiator and a black pigment on a substrate, an exposure step in which the resulting layer is irradiated on the opposite side to the substrate with actinic ray through a photomask, a developing step of developing the photopolymerizable resin layer and removing an unexposed portion thereof. The method may include a heating step before the exposure step, or a post-exposure step and/or a post-baking step after the developing step.

After forming a substrate having a black matrix pattern, a layering step of providing a fluorine-containing compound layer on the black matrix pattern surface of the substrate having a black matrix pattern is preferably performed by lamination (thermocompression bonding). The temperature of the lamination roll upon lamination (thermocompression bonding) is preferably 40 to 130° C.; the transfer speed of the substrate is preferably 0.2 m to 4 m per minute; and the pressure of the lamination roll is preferably 0.05 MPa to 1 MPa. A substrate having a black matrix pattern can be formed by peeling off the supporting film after the layering step.

Also, the layering step in the manufacturing method may be before the post-exposure step or the post-baking step as long as it is after the developing step.

The method for manufacturing a substrate having a black matrix pattern of the present invention is preferred compared to a manufacturing method in which a fluorine-containing compound layer is directly coated on a photopolymerizable resin layer formed on a substrate and dried, followed by exposure through photomask and development, in that drying steps are not employed, unevenness in film thickness is not caused when applying to a glass substrate, and photomask stays clean as a transparent supporting film keeps the fluorine-containing compound layer from coming into contact with photomask. In the present invention, productivity is significantly improved by continuously applying a fluorine-containing compound layer to a film and also continuously carrying out lamination on a substrate, compared to the case where a fluorine-containing compound layer is directly coated on a substrate one by one. Moreover, the method of the present invention is preferred in that when peeling off a fluorine-containing compound coated film or a supporting film after exposure, as a photopolymerizable resin is disposed between the fluorine-containing compound coated film or the supporting film and a substrate and does not come into contact with air upon exposure, the photopolymerizable resin is considered to be less vulnerable to oxygen inhibition, have high sensitivity to light despite the high concentration of a coloring material and be excellent in adhesion properties to glass substrates and resolution.

In the method for manufacturing a substrate having a black matrix pattern of the present invention, transferring a part or all of the fluorine-containing compound layer to the black matrix layer side in the layering step of a fluorine-containing compound coated film improves the hydrophobicity of the black matrix pattern surface and develops ink repellency, making it possible to form a black matrix pattern suitable for applying a color resist ink by an inkjet process. In the present invention, productivity is significantly improved by continuously applying a fluorine-containing compound layer to a film and also continuously laminating the layer on a substrate, compared to the case where a fluorine-containing compound layer is directly coated on a substrate one by one.

(3) Method for Manufacturing Color Filter

Next, the method for manufacturing a color filter of the present invention is described.

The method for manufacturing a color filter of the present invention includes forming the above-described substrate having a black matrix pattern and then forming pixel patterns of red, blue and green on at least a part of the substrate having a black matrix pattern, which is not covered with the black matrix pattern, using a thermosensitive or photopolymerizable color ink.

Generally, the black matrix pattern is in the form of lattices surrounding pixels. Also, each side of a lattice generally has a pattern width of 5 μm to 50 μm and the distance between lattices is 30 μm to 500 μm.

Pixel patterns of red, blue and green are formed by an inkjet process using a color ink. Inkjet processes are better than, for example, techniques of forming pixel patterns by a photolithographic process using color resist of liquid resist or dry film resist, because the inkjet processes make it possible to form pixel patterns easily at low cost as they require no exposure step with expensive mask or no developing step, can form pixel patterns regardless of irregularities and improve the yield. Known ink can be used as the thermosensitive or photopolymerizable color ink. Also, a composition containing a pigment and a dye described as examples of coloring materials in the present invention, a monomer having an ethylenically unsaturated double bond and a thermal or photopolymerization initiator, whose viscosity is accordingly adjusted using a solvent may be used. For example, the coloring ink described in Example 1 of JP-A-2004-213033 may be used. Owing to the surface ink repellency according to the present invention, even the color ink spilt on black matrix due to the problem with the ink landing accuracy flows down the wall and can fill the space for color pixels, and even when injecting a coloring ink into pixels to a height greater than the thickness of the black matrix pattern, ink can be held without running down into neighboring pixels.

In the method for manufacturing a substrate having a black matrix pattern of the present invention, an ink receiving layer may be disposed between the substrate and the black matrix layer. The ink receiving layer means a layer compatible with ink, which is previously formed within a frame surrounded by black matrix patterns on a substrate when manufacturing a color filter by an inkjet process, effectively allowing a color ink to easily land on the inside of black matrix patterns. A substrate having a black matrix pattern can be manufactured, for example, by a technique described in Example 1 of JP-A-2000-075127, in which a film of an ink-compatible resin is coated on a substrate and a photopolymerizable resin layered film is provided on the ink receiving layer.

### EXAMPLES

The present invention is described based on Examples.

### <Contact Angle>

The contact angle means a value measured by a contact angle meter (Model CA-VE made by Kyowa Interface Science CO. LTD.) 2 seconds after dropping 1 microliter of droplets on a sample from a microsyringe. The contact angle to xylene and the contact angle to purified water were measured.

Although ink repellency is evaluated based on the measurement of contact angles of droplets in the present invention, the measured values of contact angles are not necessarily the same when employing a different method for manufacturing a substrate having a black matrix of the <Direct coating method>, the <Lamination method>, the <Post lamination method> or the <Lamination onto pattern method>, even an identical fluorine-containing compound coated film is used, because the amount of the fluorine-containing compound layer attached to black matrix is different or the surface roughness of the black matrix surface is different.

### <Photopolymerizable Resin Layered Film Method: Direct Coating Method>

### Examples 1 to 3

### Lamination Of Fluorine-Containing Compound Layer on Supporting Film

### Preparation of Fluorine-Containing Compound Coated Film

A fluorine coating agent (Novec EGC-1700 manufactured by Sumitomo 3M Ltd.; solid content by weight of fluorine resin: 2% by mass) was diluted with methyl nonafluorobutyl ether/methyl nonafluoroisobutyl ether (Novec HFE7100 manufactured by Sumitomo 3M Ltd.) which is a fluorine solvent, and the resultant was coated on a polyethylene terephthalate supporting film having a thickness of 16 μm (R340G16 manufactured by Mitsubishi Polyester Film Corporation) by a bar coater and heated at 80° C. for 2 minutes to give a supporting film having a fluorine-containing compound layer containing 100% by mass of a fluorine-containing compound (fluorine-containing compound coated film). At this stage, by properly changing the solid content by weight of the fluorine coating agent, fluorine-containing compound coated films 1 to 7 in which the layer volume of the fluorine-containing compound layer per 1 m² of the film was variable were prepared.

Since the height of a fluorine coating layer of a film formed by using a solution having a solid content by weight of 0.2% by mass prepared by diluting EGC-1700 by 10 times, was measured to be 60 nm by a profilometer, the layer volume of the fluorine-containing compound layer per 1 m² of the supporting film was calculated to be 60 nm×1000 mm×1000 mm=60 mm³. Also, assuming that the ratio of the solid content by weight A (%) to the layer volume B (mm³) of the fluorine-containing compound layer of the resulting film is B=(A/0.2)×60, the layer volume was estimated as those described in Table 1 by accordingly changing the solid content by weight.

1 μL of xylene was dropped to the coating surface of the fluorine-containing compound coated films 1 to 7 and the contact angle of droplets was measured by a contact angle meter. The results are shown in Table 1. The layer volume in the fluorine-containing compound coated films 2 to 6 is within the range of 1 to 60 mm³ per 1 m², while the layer volume in the fluorine-containing compound coated films 1 and 7 is out of the range of 1 to 60 mm³ per 1 m².

Preparation of Photopolymerizable Resin Solution

A photopolymerizable resin composition solution (A) in methyl ethyl ketone having a solid content of 10% by mass was prepared by mixing an alkali soluble polymer, a photopolymerizable compound having an ethylenically unsaturated bond, a photopolymerization initiator and a black pigment at the ratio shown below.

A-1: methyl ethyl ketone solution containing a copolymer of benzyl methacrylate/methacrylic acid=8/2(mass ratio) having a weight average molecular weight of 20,000 and acid equivalent of 430 and a binder having a solid concentration of 50%;

B-1: pentaerythritol tetraacrylate

B-2: succinic acid-modified pentaerythritol triacrylate (ARONIX manufactured by TOAGOSEI CO., LTD.)

C-1: 1-[9-ethyl-6-(2-methylbenzoyl)-9.H.-carbazol-3-yl]ethan-1-one oxime-O-acetate (IRGACURE OXE-02 manufactured by Ciba Specialty Chemicals)

D-1: triethylene glycol-bis-[3-(3-tertiarybutyl-5-methyl-4-hydroxyphenyl)propionate] (IRGANOX 245 manufactured by Ciba Specialty Chemicals)

E-1: carbon black

A photopolymerizable resin composition solution (A) in methyl ethyl ketone having a solid content of 10% by mass was prepared by mixing 100 parts by mass of A-1, 15 parts by mass of B-1, 5 parts by mass of B-2, 5 parts by mass of C-1, 0.3 part by mass of D-1 and 45 parts by mass of E-1.

Preparation of Photopolymerizable Resin Layered Film

A photopolymerizable resin layer having a thickness of 1 μm was formed by uniformly applying the photopolymerizable resin composition solution (A) in methyl ethyl ketone to the fluorine-containing compound layer of the fluorine-containing compound coated film 2, 3 or 5 in Table 1 using a bar coater and subsequently drying the same in a dryer at 95° C. for 5 minutes. Then a polypropylene protective film having a thickness of 20 μm (ALPHAN E-200A manufactured by OJI SPECIALTY PAPER Co., Ltd.) was laminated to the resulting photopolymerizable resin layer to give photopolymerizable resin layered films 2, 3 and 5. Film properties of the photopolymerizable resin layered films were evaluated as shown in Table 2: [symbol] : no defects; ◯: 5 or less small cissings or cracks found in the photopolymerizable resin layer per 1 m²; x: 6 or more cissings or cracks found per 1 m² or not usable due to a large defect occupying 10% or more of the area of the photopolymerizable resin layered film.

Formation of Glass Substrate Having Black Matrix Pattern

The protective film of the above-described photopolymerizable resin layered films 2, 3 and 5 was peeled off and then the layered films were each laminated on a 10 cm square 0.7 mm thick alkali-free glass substrate at 95° C. at a speed of 1 m per minute. Then the supporting film was peeled off to form a photopolymerizable resin layer and a fluorine-containing compound layer on a substrate. The resultant was exposed on the side of the fluorine-containing compound layer through a glass photomask having a black matrix pattern of a line width/space width of 10 μm/90 μm and a solid pattern with a super high pressure mercury lamp (HMW-801 manufactured by ORC MANUFACTURING CO., LTD.) at 500 mJ/cm². Development was carried out by dissolving and removing uncured portions of the photopolymerizable resin layer by spraying a 0.2% by mass aqueous sodium carbonate solution at 25° C. The standard developing time was 1.5 times the time during which uncured portions of the photopolymerizable resin layer have been removed from the glass substrate (defined as “breakpoint”). Thereafter post-baking of the developed product was performed at 240° C. for 60 minutes to form glass substrates having black matrix with a fluorine-containing compound layer of Examples 1, 2 and 3.

It took 1 minute per substrate to laminate a photopolymerizable resin layered film on a glass substrate to form a black matrix layer with a fluorine-containing compound layer.

Evaluation of Glass Substrate Having Black Matrix Pattern

(1) Pattern Formation

Whether a black matrix pattern of a line width/space width=10 μm/90 μm was formed or not was visually observed by an optical microscope.

(2) Ink repellency The contact angle to xylene and the contact angle to purified water on a solid pattern black matrix surface (BM surface) and a glass substrate were measured by a contact angle meter based on drop measurement.

Evaluation results are shown in Table 2.

### Comparative Example 1

Photopolymerizable resin layered film 1 in Table 2 was prepared in the same manner as in Example 1 except for using fluorine-containing compound coated film 1 in Table 1. A glass substrate having black matrix with a fluorine-containing compound layer was formed in the same manner as in Example 1 except for using the photopolymerizable resin layered film 1

As a result of the evaluation of the ink repellency, the black matrix surface had a contact angle to water of 72 degrees and a contact angle to xylene of 2 degrees, showing insufficient ink repellency.

### Comparative Example 2

The photopolymerizable resin composition solution (A) in methyl ethyl ketone was uniformly coated on the fluorine-containing compound coated film 7 in Table 1 using a bar coater and dried in a dryer at 95° C. for 5 minutes. As a result, the photopolymerizable resin layer on the film had 10 or more cissings or cracks, showing that a photopolymerizable resin layer having appropriate film properties could not be formed.

### <Photopolymerizable Resin Layered Film Method: Lamination Method>

### Examples 4 to 6

### Preparation of Photopolymerizable Resin Layered Film

A photopolymerizable resin layer having a thickness of 1 μm was formed by applying the photopolymerizable resin composition solution (A) in methyl ethyl ketone to a polyethylene terephthalate supporting film having a thickness of 16 μm (R340G16 manufactured by Mitsubishi Polyester Film Corporation) by a bar coater and subsequently drying the same at 95° C. for 5 minutes. Thereafter the above-described fluorine-containing compound coated film 2, 3 or 5 was each superposed over the resulting photopolymerizable resin layer so that the photopolymerizable resin layer came into contact with the fluorine-containing compound layer, for lamination at 95° C. at a speed of 1 m per minute to give photopolymerizable resin layered films 12, 13, 15.

Formation of Glass Substrate Having Black Matrix Pattern

The supporting film in the above-described photopolymerizable resin layered film 12, 13 or 15 was peeled off the photopolymerizable resin layer, and then the photopolymerizable resin layer was laminated to a 10 cm square 0.7 mm thick alkali-free glass substrate at 95° C. at a speed of 1 m per minute, forming the photopolymerizable resin layer and the fluorine-containing compound layer on the substrate. The resultant was exposed on the side of the supporting film through a glass photomask having a pattern of a line width/space width of 10 μm/90 μm with a super high pressure mercury lamp (HMW-801 manufactured by ORC MANUFACTURING CO., LTD.) at 100 mJ/cm². After peeling off the supporting film, development was carried out by dissolving and removing uncured portions of the photopolymerizable resin layer by spraying a 0.2% by mass aqueous sodium carbonate solution at 25° C. The standard developing time was 1.5 times the breakpoint. Thereafter post-baking was performed at 240° C. for 60 minutes to form glass substrates having a black matrix pattern of Examples 4, 5 and 6.

It took 1 minute per substrate to laminate a photopolymerizable resin layered film on a glass substrate to form a black matrix layer with a fluorine-containing compound layer.

Evaluation of Glass Substrate Having Black Matrix Pattern

The substrates were evaluated in the same manner as in Example 1. Results are shown in Table 3.

### Comparative Example 3

A photopolymerizable resin layered film 11 in Table 3 was prepared in the same manner as in Example 4 except for using the fluorine-containing compound coated film 1 in Table 1. A glass substrate having black matrix with a fluorine-containing compound layer was formed in the same manner as in Example 4 except for using the photopolymerizable resin layered film 11.

As a result of the evaluation of the ink repellency, the black matrix surface had a contact angle to water of 72 degrees and a contact angle to xylene of 2 degrees, showing insufficient ink repellency.

### Comparative Example 4

A photopolymerizable resin layered film 17 in Table 3 was prepared in the same manner as in Example 4 except for using the fluorine-containing compound coated film 7 in Table 1. Attempts were made to form a glass substrate having black matrix with a fluorine-containing compound layer in the same manner as in Example 4 except for using the photopolymerizable resin layered film 17. Despite extending the developing time to 2 minutes in the process, uncured portions of the photopolymerizable resin layer were not developed.

### <Post Lamination Method>

### Examples 7 to 11

A photopolymerizable resin layered film was prepared by forming a photopolymerizable resin layer having a thickness of 1 μm by applying the photopolymerizable resin composition solution (A) in methyl ethyl ketone to a polyethylene terephthalate supporting film having a thickness of 16 μm (R340G16 manufactured by Mitsubishi Polyester Film Corporation) by a bar coater and subsequently drying the same at 95° C. for 5 minutes. Subsequently, the photopolymerizable resin layer of the resulting photopolymerizable resin layered film and a 10 cm square 0.7 mm thick alkali-free glass substrate were laminated at 95° C. at a speed of 1 m per minute, and then the supporting film was peeled off, forming the photopolymerizable resin layer on the substrate.

The above-described substrate on which a photopolymerizable resin layer was formed and each of the above-described fluorine-containing compound coated films 2, 3, 4, 5 and 6 were superposed so that the photopolymerizable resin layer comes into contact with the fluorine-containing compound layer, and laminated at a roll temperature of 120° C. at a speed of 1 m per minute. The resultant was exposed on the side of the supporting film through a glass photomask having a pattern of a line width/space width of 10 μm/90 μm with a super high pressure mercury lamp (HMW-801 manufactured by ORC MANUFACTURING CO., LTD.) at 100 mJ/cm². After peeling off the supporting film, development was carried out by dissolving and removing uncured portions of the photopolymerizable resin layer by spraying a 0.2% by mass aqueous sodium carbonate solution at 25° C. The standard developing time was 1.5 times the breakpoint. Thereafter post-baking was performed at 240° C. for 60 minutes to form glass substrates having a black matrix pattern of Examples 7, 8, 9, 10 and 11.

It took 3 minutes per substrate, including the travel time of the glass substrate, to perform lamination twice for laminating a photopolymerizable resin layered film on a glass substrate to form a black matrix layer and then laminating the photopolymerizable resin layered film and the fluorine-containing compound coated film to form a black matrix layer with a fluorine-containing compound layer on the glass substrate.

Evaluation of Glass Substrate Having Black Matrix Pattern

The substrates were evaluated in the same manner as in Example 1. Results are shown in Table 4.

### Examples 12 to 15

A fluorine surface treatment agent containing a thermosetting component (Novec EGC-1720 manufactured by Sumitomo 3M Ltd.; solid content by weight of fluorine polymer: 0.1% by mass) was diluted with methyl nonafluorobutyl ether/methyl nonafluoroisobutyl ether (Novec (registered trademark) HFE7100 manufactured by Sumitomo 3M Ltd.) which is a fluorine solvent, and the resultant was coated on a polyethylene terephthalate supporting film having a thickness of 16 μm (R340G16 manufactured by Mitsubishi Polyester Film Corporation) by a bar coater and heated at 95° C. for 5 minutes to form a supporting film having a fluorine-containing compound layer containing 100% by mass of a fluorine-containing compound (fluorine-containing compound coated film). At this stage, by properly changing the solid content of the fluorine surface treatment agent, fluorine-containing compound coated films 8 and 9 in which the layer volume of the fluorine-containing compound layer per 1 m² of the film was variable were prepared as shown in Table 1.

Since the height of a fluorine surface treatment agent layer of a film formed by using the above-described fluorine surface treatment agent solution having a solid content by weight of 0.1% by mass, was measured to be 30 nm by a profilometer, the layer volume of the fluorine-containing compound layer per 1 m² of the film was calculated to be 30 nm×1000 mm×1000 mm=30 mm³. Also, assuming that the ratio of solid content A (%) by weight to the layer volume B (mm³) of the fluorine-containing compound layer of the resulting film is B=(A/0.1)×30, the layer volume was estimated as those described in Table 1 by accordingly changing the solid content by weight.

A copolymerization oligomer containing a perfluoroalkyl group-containing acrylate or methacrylate as a main component (MODIPER (registered trademark) F200 manufactured by NOF Corporation; solid content by weight of fluorine block copolymer: 30% by mass) was diluted with methyl ethyl ketone, and the resultant was coated on a polyethylene terephthalate supporting film having a thickness of 16 μm (R340G16 manufactured by Mitsubishi Polyester Film Corporation) by a bar coater and heated at 95° C. for 5 minutes to form a supporting film having a fluorine-containing compound layer containing 100% by mass of a fluorine-containing compound (fluorine-containing compound coated film). At this stage, by properly changing the solid content of the copolymerization oligomer containing a perfluoroalkyl group-containing acrylate or methacrylate as a main component, fluorine-containing compound coated films 10 and 11 in which the layer volume of the organic compound containing a fluorine-containing compound per 1 m² of the film was variable were prepared as shown in Table 1.

Since the height of a fluorine coating layer on a film formed by using a methyl ethyl ketone solution having a solid content by weight of 0.2% by mass prepared by diluting MODIPER (registered trademark) F200 by 150 times, was measured to be 60 nm by a profilometer, the layer volume of the fluorine-containing compound layer per 1 m² of the film was calculated to be 60 nm×1000 mm×1000 mm=60 mm³. Assuming that the ratio of solid content A (%) by weight to the layer volume B (mm³) of the fluorine-containing compound layer of the resulting film is B=(A/0.2)×60, the layer volume was estimated as those described in Table 1 by accordingly changing the solid content by weight.

1 μl of xylene was dropped to the surface of the fluorine-containing compound coated films 8 to 11 and the contact angle of droplets was measured by a contact angle meter. Results are shown in Table 1.

A photopolymerizable resin layered film having a 1 μm thick photopolymerizable resin layer was prepared by applying the photopolymerizable resin composition solution (A) in methyl ethyl ketone to a polyethylene terephthalate supporting film having a thickness of 16 μm (R340G16 manufactured by Mitsubishi Polyester Film Corporation) by a bar coater and subsequently drying the same at 95° C. for 5 minutes. Subsequently, the photopolymerizable resin surface of the resulting photopolymerizable resin layered film and a 10 cm square 0.7 mm thick alkali-free glass substrate were laminated at 95° C. at a speed of 1 m per minute, and then the supporting film was peeled off, forming the photopolymerizable resin layer on the substrate.

The above-described substrate on which a photopolymerizable resin layer was formed and each of the above-described fluorine-containing compound coated films 8, 9, 10 and 11 were superposed so that the photopolymerizable resin layer came into contact with the fluorine-containing compound layer, and laminated at a roll temperature of 120° C. at a speed of 1 m per minute. The resultant was exposed on the side of the supporting film through a glass photomask having a pattern of a line width/space width of 10 μm/90 μm with a super high pressure mercury lamp (HMW-801 manufactured by ORC MANUFACTURING CO., LTD.) at 100 mJ/cm². After peeling off the supporting film, development was carried out by dissolving and removing uncured portions of the photopolymerizable resin layer by spraying a 0.2% by mass aqueous sodium carbonate solution at 25° C. The standard developing time was 1.5 times the breakpoint. Thereafter post-baking was performed at 240° C. for 60 minutes to form glass substrates having a black matrix pattern of Examples 12, 13, 14 and 15.

It took 3 minutes per substrate, including the travel time of the glass substrate, to perform lamination twice for laminating a photopolymerizable resin layered film on a glass substrate to form a black matrix layer and then laminating the black resin layered film and the fluorine-containing compound coated film to form a black matrix layer with a fluorine-containing compound layer on the glass substrate.

Evaluation of Glass Substrate Having Black Matrix Pattern

The substrates were evaluated in the same manner as in Example 1. Results are shown in Table 4.

### Comparative Example 5

A glass substrate having black matrix with a fluorine-containing compound layer was formed in the same manner as in Example 7 except for using the fluorine-containing compound coated film 7 in Table 1.

As a result of the evaluation of the ink repellency, the black matrix surface had a contact angle to water of 72 degrees and a contact angle to xylene of 2 degrees, showing insufficient ink repellency.

### Comparative Example 6

Attempts were made to form a glass substrate having black matrix with a fluorine-containing compound layer in the same manner as in Example 6 except for using the fluorine-containing compound coated film 7 in Table 1. Despite extending the developing time to 2 minutes in the process, uncured portions of the photopolymerizable resin layer were not developed.

### Comparative Examples 7, 8

Experiments were performed in the same manner as in Example 7 except for using the following film instead of a fluorine-containing compound coated film. For lamination, the substrate and the film were superposed so that the photopolymerizable resin layer came into contact with the surface on which a silicone stripping agent was coated.

### Comparative Example 7

PET25GS manufactured by Lintec Corporation (polyethylene terephthalate film having a thickness of 25 μm with a silicone stripping agent coated on one side)

### Comparative Example 8

PET38-2010 manufactured by Lintec Corporation (polyethylene terephthalate film having a thickness of 38 μm with a silicone stripping agent coated on one side)

Evaluation results are shown in Table 4.

Both of the resulting substrates had a contact angle to xylene of 10 degrees or lower, showing insufficient ink repellency.

<Lamination onto Pattern Method>

### Example 16

A photopolymerizable resin layered film having a 1 μm thick photopolymerizable resin layer was prepared by applying the photopolymerizable resin composition solution (A) in methyl ethyl ketone to a polyethylene terephthalate supporting film having a thickness of 16 μm (R340G16 manufactured by Mitsubishi Polyester Film Corporation) by a bar coater and subsequently drying the same at 95° C. for 5 minutes. Subsequently, the photopolymerizable resin surface of the resulting photopolymerizable resin layered film and a 10 cm square 0.7 mm thick alkali-free glass substrate were laminated at 95° C. at a speed of 1 m per minute, and then the resultant was exposed on the side of the supporting film through a glass photomask having a pattern of a line width/space width of 10 μm/90 μm with a super high pressure mercury lamp (HMW-801 manufactured by ORC MANUFACTURING CO., LTD.) at 100 mJ/cm². After peeling off the supporting film, development was carried out by dissolving and removing uncured portions of the photopolymerizable resin layer by spraying a 0.2% by mass aqueous sodium carbonate solution at 25° C. The standard developing time was 1.5 times the breakpoint. The glass substrate and the fluorine-containing compound coated film 4 in Table 1 were laminated at 120° C. at a speed of 1 m per minute so that the black matrix pattern comes into contact with the fluorine-containing compound layer. The supporting film was peeled off to form a glass substrate having a black matrix pattern. Thereafter post-baking was performed at 240° C. for 60 minutes.

It took 1 minute per substrate to laminate a glass substrate having a black matrix pattern and a fluorine-containing compound coated film to form a substrate having a black matrix pattern.

Evaluation of Glass Substrate Having Black Matrix Pattern

As a result of the evaluation of the ink repellency, the black matrix surface had a contact angle to water of 89 degrees and a contact angle to xylene of 44 degrees, showing sufficient ink repellency.

### Example 17

A photopolymerizable resin layered film having a 1 μm thick photopolymerizable resin layer was prepared by applying the photopolymerizable resin composition solution (A) in methyl ethyl ketone to a polyethylene terephthalate supporting film having a thickness of 16 μm (R340G16 manufactured by Mitsubishi Polyester Film Corporation) by a bar coater and subsequently drying the same at 95° C. for 5 minutes. Subsequently, the photopolymerizable resin surface of the resulting photopolymerizable resin layered film and a 10 cm square 0.7 mm thick alkali-free glass substrate were laminated at 95° C. at a speed of 1 m per minute, and then the resultant was exposed on the side of the supporting film through a glass photomask having a pattern of a line width/space width of 10 μm/90 μm with a super high pressure mercury lamp (HMW-801 manufactured by ORC MANUFACTURING CO., LTD.) at 100 mJ/cm². After peeling off the supporting film, development was carried out by dissolving and removing uncured portions of the photopolymerizable resin layer by spraying a 0.2% by mass aqueous sodium carbonate solution at 25° C. The standard developing time was 1.5 times the breakpoint. Thereafter post-baking was performed at 240° C. for 60 minutes to form a glass substrate having a black matrix pattern.

The above glass substrate having a black matrix pattern and the fluorine-containing compound coated film 4 in Table 1 were laminated at 120° C. at a speed of 1 m per minute so that the black matrix pattern comes into contact with the fluorine-containing compound layer. The supporting film was peeled off to form a glass substrate having a black matrix pattern.

It took 1 minute per substrate to laminate a glass substrate having a black matrix pattern and a fluorine-containing compound coated film to form a substrate having a black matrix pattern.

Evaluation of Glass Substrate Having Black Matrix Pattern

As a result of evaluation of ink repellency, the black matrix surface had a contact angle to water of 119 degrees and a contact angle to xylene of 58 degrees, showing sufficient ink repellency.

### <Post Lamination Method>

### Examples 18 to 22

### Preparation of Fluorine-Containing Compound Coated Film 12, 13

DICGUARD NH-15 manufactured by Dainippon Ink & Chemicals Incorporated (solid content by weight: 15% by mass) and DICGUARD NH-10 manufactured by Dainippon Ink & Chemicals Incorporated (solid content by weight: 10% by mass), which are fluorine surface treatment agents containing a thermosetting component, were each diluted with methyl ethyl ketone, and the resultant was coated on a polyethylene terephthalate supporting film having a thickness of 16 μm (R340G16 manufactured by Mitsubishi Polyester Film Corporation) by a bar coater and heated at 95° C. for 15 minutes and warmed at 50° C. for 12 hours to form a supporting films 12, 13 having a fluorine-containing compound layer containing 100% by mass of a fluorine-containing compound (fluorine-containing compound coated film).

Since the height of a fluorine surface treatment agent layer of a film formed by using the above-described fluorine surface treatment agent solution having a solid content by weight of 0.2% by mass, was measured to be 60 nm by a profilometer, the amount of the organic compound containing the fluorine-containing compound per 1 m² of the film was calculated to be 60 nm×1000 mm×1000 mm=60 mm³. Also, assuming that the ratio of solid content A (%) by weight to the layer volume B (mm³) of the fluorine-containing compound layer of the resulting film is B=(A/0.2)×60, the layer volume was estimated as those described in Table 5 by accordingly changing the solid content by weight.

Preparation of Fluorine-Containing Compound Coated Film 14 to 18

A-1: methyl ethyl ketone solution containing a copolymer of benzyl methacrylate/methacrylic acid=8/2(mass ratio) having a weight average molecular weight of 20,000 and acid equivalent of 430 and a binder having a solid concentration of 50%;

B-1: pentaerythritol tetraacrylate

B-2: succinic acid-modified pentaerythritol triacrylate (ARONIX manufactured by TOAGOSEI CO., LTD.)

C-1: 1-[9-ethyl-6-(2-methylbenzoyl)-9.H.-carbazol-3-yl]-ethan-1-one oxime-O-acetate (IRGACURE OXE-02 manufactured by Ciba Specialty Chemicals)

D-1: triethylene glycol-bis-[3-(3-tertiarybutyl-5-methyl-4-hydroxyphenyl)propionate] (IRGANOX 245 manufactured by Ciba Specialty Chemicals)

A photopolymerizable resin composition solution (B) in methyl ethyl ketone having a solid content of 10% by mass was prepared by mixing 40 parts by mass of the above A-1, 2 parts by mass of B-1, 4 parts by mass of B-2, 3 parts by mass of C-1 and 0.2 part by mass of D-1 and diluting with methyl ethyl ketone.

A copolymerization oligomer containing a perfluoroalkyl group-containing acrylate or methacrylate as a main component (MODIPER (registered trademark) F200 manufactured by NOF Corporation; solid content by weight of fluorine block copolymer: 30% by mass) and the above-described photopolymerizable resin composition solution (B) in methyl ethyl ketone were mixed at ratios shown in Table 6. The mixture was diluted with methyl ethyl ketone and coated on a polyethylene terephthalate supporting film having a thickness of 16 μm (R340G16 manufactured by Mitsubishi Polyester Film Corporation) by a bar coater and heated at 95° C. for 5 minutes to form fluorine-containing compound coated films 14 to 18. At this stage, by properly changing the ratio of the solid content of the copolymerization oligomer containing a perfluoroalkyl group-containing acrylate or methacrylate as a main component as shown in Table 6, fluorine-containing compound coated films 14 to 18 in which the amount of the fluorine-containing compound in the organic compound layer was variable were prepared as shown in Table 6. The fluorine-containing compound coated films 16 to 18 correspond to the films according to the present invention, while the amount of the fluorine-containing compound in the fluorine-containing compound layer of the fluorine-containing compound coated films 14 and 15 differs from that in the present invention. Since the height of a fluorine-containing compound layer of a film formed by using a methyl ethyl ketone solution having a solid content by weight of 0.2% by mass prepared by mixing MODIPER (registered trademark) F200 and the above-described photopolymerizable resin composition solution (B) in methyl ethyl ketone, was measured to be 60 nm by a profilometer, the layer volume of the fluorine-containing compound layer per 1 m² of the film was calculated to be 60 nm×1000 mm×1000 mm=60 mm³. Assuming that the ratio of solid content A (%) by weight to the layer volume B (mm³) of the fluorine-containing compound layer of the resulting film is B=(A/0.2)×60, the layer volume was estimated as those described in Table 6 by accordingly changing the solid content by weight of the composition containing a fluorine-containing compound.

1 μL of xylene was dropped to the coating surface of the fluorine-containing compound coated films 14 to 18 and the contact angle of droplets was measured by a contact angle meter. Results are shown in Table 6.

Preparation of Photopolymerizable Resin Layered Film

A photopolymerizable resin layer having a thickness of 1 μm was formed by applying the photopolymerizable resin composition solution (A) in methyl ethyl ketone to a polyethylene terephthalate supporting film having a thickness of 16 μm (R340G16 manufactured by Mitsubishi Polyester Film Corporation) by a bar coater and subsequently drying the same at 95° C. for 5 minutes. Thereafter the above-described fluorine-containing compound coated films 12 to 18 were each superposed over the resulting photopolymerizable resin layer so that the photopolymerizable resin layer comes into contact with the fluorine-containing compound layer, and laminated at 95° C. at a speed of 1 m per minute to give photopolymerizable resin layered films 22 to 28. The photopolymerizable resin layered films 22, 23, 26, 27 and 28 correspond to the photopolymerizable resin layered film according to the present invention, while the content of the fluorine-containing compound in the fluorine-containing compound layer of the photopolymerizable resin layered films 24 and 25 differs from that in the present invention.

Formation of Glass Substrate Having Black Matrix Pattern

The supporting film in the above-described photopolymerizable resin layered film 22, 23, 26, 27 or 28 was peeled off the photopolymerizable resin layer, and then the photopolymerizable resin layer was laminated to a 10 cm square 0.7 mm thick alkali-free glass substrate at 95° C. at a speed of 1 m per minute, forming the photopolymerizable resin layer and the fluorine-containing compound layer on the substrate. The resultant was exposed on the side of the supporting film through a glass photomask having a pattern of a line width/space width of 10 μm/90 μm with a super high pressure mercury lamp (HMW-801 manufactured by ORC MANUFACTURING CO., LTD.) at 100 mJ/cm². After peeling off the supporting film, development was carried out by dissolving and removing uncured portions of the photopolymerizable resin layer by spraying a 0.2% by mass aqueous sodium carbonate solution at 25° C. The standard developing time was 1.5 times the breakpoint. Thereafter post-baking was performed at 240° C. for 60 minutes to form glass substrates having a black matrix pattern of Examples 18 to 22.

It took 1 minute per substrate to laminate a photopolymerizable resin layered film on a glass substrate to form a black matrix layer with a fluorine-containing compound layer.

Evaluation of Glass Substrate Having Black Matrix Pattern

The substrates were evaluated in the same manner as in Example 1. Results are shown in Table 7.

### Comparative Examples 9, 10

Photopolymerizable resin layered films 24, 25 were prepared in the same manner as in Example 20 except for using fluorine-containing compound coated films 14, 15 in Table 6. A glass substrate having black matrix with a fluorine-containing compound layer was formed in the same manner as in Example 20 except for using the photopolymerizable resin layered films 24, 25 as Comparative Examples 9, 10.

As a result of the evaluation of the ink repellency, the black matrix surface had a contact angle to xylene of 9 degrees in Comparative Example 9 and 16 degrees in Comparative Example 10, showing insufficient ink repellency.

By means of the photopolymerizable resin layered film and the fluorine-containing compound coated film of the present invention, high ink repellency can be given only to the top surface of a black matrix pattern by an easy method without increasing the ink repellency of the glass substrate.

TABLE 1

| | | Volume of fluorine- | | |
|---|---|---|---|---|
| | | containing compound | | |
| | Fluorine- | layer per 1 m² of | Contact angle | |
| Name of fluorine-containing | containing | supporting film | (degree) | |
| compound coated film | compound | (mm³) | Water | Xylene |
| Fluorine-containing compound coated film 1 | EGC-1700 | 0.4 mm³ | 89 | 4 |
| Fluorine-containing compound coated film 2 | EGC-1700 | 1.0 mm³ | 103 | 50 |
| Fluorine-containing compound coated film 3 | EGC-1700 | 4.0 mm³ | 103 | 61 |
| Fluorine-containing compound coated film 4 | EGC-1700 | 12 mm³ | 104 | 62 |
| Fluorine-containing compound coated film 5 | EGC-1700 | 40 mm³ | 106 | 61 |
| Fluorine-containing compound coated film 6 | EGC-1700 | 60 mm³ | 105 | 63 |
| Fluorine-containing compound coated film 7 | EGC-1700 | 150 mm³ | 106 | 62 |
| Fluorine-containing compound coated film 8 | EGC-1720 | 2.0 mm³ | 94 | 41 |
| Fluorine-containing compound coated film 9 | EGC-1720 | 6.0 mm³ | 107 | 58 |
| Fluorine-containing compound coated film 10 | MODIPER F200 | 2.0 mm³ | 96 | 20 |
| Fluorine-containing compound coated film 11 | MODIPER F200 | 6.0 mm³ | 110 | 39 |

TABLE 2

| | | Photopolymerizable resin | | Contact angle (degree) | | | | |
|---|---|---|---|---|---|---|---|---|
| | Fluorine-containing | layered film prepared | | Water | | Xylene | | |
| | compound coated film | | Film | BM | | BM | | Pattern |
| | in Table 1 to be used | Name | property | surface | Glass | surface | Glass | formation |
| Ex. 1 | Fluorine-containing | Photopolymerizable resin | [symbol] | 107 | 67 | 47 | 6 | ◯ |
| | compound coated film 2 | layered film 2 | | | | | | |
| Ex. 2 | Fluorine-containing | Photopolymerizable resin | [symbol] | 111 | 79 | 60 | 8 | ◯ |
| | compound coated film 3 | layered film 3 | | | | | | |
| Ex. 3 | Fluorine-containing | Photopolymerizable resin | ◯ | 111 | 67 | 58 | 7 | ◯ |
| | compound coated film 5 | layered film 5 | | | | | | |
| Comp. Ex. 1 | Fluorine-containing | Photopolymerizable resin | [symbol] | 72 | 66 | 2 | 2 | ◯ |
| | compound coated film 1 | layered film 1 | | | | | | |
| Comp. Ex. 2 | Fluorine-containing | Photopolymerizable resin | X | | | | | Undeveloped |
| | compound coated film 7 | layered film 7 | | | | | | |

TABLE 3

| | | Photopolymerizable resin | | Contact angle (degree) | | | | |
|---|---|---|---|---|---|---|---|---|
| | Fluorine-containing | layered film prepared | | Water | | Xylene | | |
| | compound coated film | | Film | BM | | BM | | Pattern |
| | in Table 1 to be used | Name | property | surface | Glass | surface | Glass | formation |
| Ex. 4 | Fluorine-containing | Photopolymerizable resin | [symbol] | 118 | 60 | 64 | 6 | ◯ |
| | compound coated film 2 | layered film 12 | | | | | | |
| Ex. 5 | Fluorine-containing | Photopolymerizable resin | [symbol] | 116 | 64 | 56 | 3 | ◯ |
| | compound coated film 3 | layered film 13 | | | | | | |
| EX. 6 | Fluorine-containing | Photopolymerizable resin | [symbol] | 111 | 61 | 63 | 6 | ◯ |
| | compound coated film 5 | layered film 15 | | | | | | |
| Comp. Ex. 3 | Fluorine-containing | Photopolymerizable resin | [symbol] | 72 | 66 | 2 | 2 | ◯ |
| | compound coated film 1 | layered film 11 | | | | | | |
| Comp. Ex. 4 | Fluorine-containing | Photopolymerizable resin | [symbol] | | | | | Undeveloped |
| | compound coated film 7 | layered film 17 | | | | | | |

TABLE 4

| | | Contact angle (degree) | | | | |
|---|---|---|---|---|---|---|
| | | Water | | Xylene | | |
| | Fluorine-containing compound | BM | | BM | | Pattern |
| | coated film in Table 1 to be used | surface | Glass | surface | Glass | formation |
| Ex. 7 | Fluorine-containing compound coated film 2 | 110 | 67 | 55 | 2 | ◯ |
| Ex. 8 | Fluorine-containing compound coated film 3 | 115 | 70 | 64 | 2 | ◯ |
| Ex. 9 | Fluorine-containing compound coated film 4 | 117 | 73 | 64 | 2 | ◯ |
| Ex. 10 | Fluorine-containing compound coated film 5 | 110 | 69 | 63 | 3 | ◯ |
| Ex. 11 | Fluorine-containing compound coated film 6 | 107 | 70 | 64 | 4 | ◯ |
| Ex. 12 | Fluorine-containing compound coated film 8 | 101 | 76 | 31 | 5 | ◯ |
| Ex. 13 | Fluorine-containing compound coated film 9 | 117 | 73 | 60 | 3 | ◯ |
| Ex. 14 | Fluorine-containing compound coated film 10 | 102 | 78 | 29 | 4 | ◯ |
| Ex. 15 | Fluorine-containing compound coated film 11 | 120 | 72 | 49 | 4 | ◯ |
| Comp. Ex. 5 | Fluorine-containing compound coated film 1 | 72 | 66 | 2 | 2 | ◯ |
| Comp. Ex. 6 | Fluorine-containing compound coated film 7 | | | | | Undeveloped |
| Comp. Ex. 7 | PET25GS manufactured by Lintec Corporation | 101 | 70 | 10 | 4 | ◯ |
| Comp. Ex. 8 | PET38-2010 manufactured by Lintec Corporation | 105 | 73 | 7 | 5 | ◯ |
| Ex. 16 | Fluorine-containing compound coated film 4 | 89 | 80 | 44 | 11 | ◯ |
| Ex. 17 | Fluorine-containing compound coated film 4 | 119 | 82 | 58 | 12 | ◯ |

TABLE 5

| | | Volume of | |
|---|---|---|---|
| | | fluorine-containing | |
| | | compound layer | Contact |
| | Fluorine- | per 1 m² of | angle |
| Name of fluorine-containing | containing | supporting film | (degree) |
| compound coated film | compound | (mm³) | Xylene |
| Fluorine-containing | NH-15 | 6.0 mm³ | 63 |
| compound coated film 12 | | | |
| Fluorine-containing | NH-10 | 6.0 mm³ | 37 |
| compound coated film 13 | | | |

TABLE 6

| | | | | Photopolymerizable | | |
|---|---|---|---|---|---|---|
| | | Volume of | | resin composition | | |
| | | fluorine-containing | MODIPER | solution (B) in methyl | | |
| | | compound layer | F200 | ethyl ketone | Ratio of fluorine- | |
| Name of fluorine- | Fluorine- | per 1 m² of | Solid content | Solid content | containing compound | Contact angle |
| containing compound | containing | supporting film | by weight: | by weight: | in fluorine-containing | (degree) |
| coated film | compound | (mm³) | 30% by weight | 10% by weight | compound layer | Xylene |
| Fluorine-containing | MODIPER F200 | 60 mm³ | 0.010 | 0.970 | 3 wt % | 10 |
| compound coated film 14 | | | | | | |
| Fluorine-containing | MODIPER F200 | 60 mm³ | 0.033 | 0.900 | 10 wt % | 18 |
| compound coated film 15 | | | | | | |
| Fluorine-containing | MODIPER F200 | 60 mm³ | 0.100 | 0.700 | 30 wt % | 28 |
| compound coated film 16 | | | | | | |
| Fluorine-containing | MODIPER F200 | 60 mm³ | 0.167 | 0.500 | 50 wt % | 38 |
| compound coated film 17 | | | | | | |
| Fluorine-containing | MODIPER F200 | 60 mm³ | 0.233 | 0.300 | 70 wt % | 41 |
| compound coated film 18 | | | | | | |

TABLE 7

| | | | | Contact angle | |
|---|---|---|---|---|---|
| | | Photopolymerizable resin | | (degree) | |
| | Fluorine-containing compound | layered film prepared | | Xylene | |
| | coated film in Table 5, 6 to be used | Name | Film property | BM surface | Pattern formation |
| Ex. 18 | Fluorine-containing compound | Photopolymerizable resin | [symbol] | 60 | ◯ |
| | coated film 12 | layered film 22 | | | |
| Ex. 19 | Fluorine-containing compound | Photopolymerizable resin | [symbol] | 52 | ◯ |
| | coated film 13 | layered film 23 | | | |
| Ex. 20 | Fluorine-containing compound | Photopolymerizable resin | [symbol] | 34 | ◯ |
| | coated film 16 | layered film 26 | | | |
| Ex. 21 | Fluorine-containing compound | Photopolymerizable resin | [symbol] | 44 | ◯ |
| | coated film 17 | layered film 27 | | | |
| Ex. 22 | Fluorine-containing compound | Photopolymerizable resin | [symbol] | 46 | ◯ |
| | coated film 18 | layered film 28 | | | |
| Comp. Ex. 9 | Fluorine-containing compound | Photopolymerizable resin | [symbol] | 9 | ◯ |
| | coated film 14 | layered film 24 | | | |
| Comp. Ex. 10 | Fluorine-containing compound | Photopolymerizable resin | [symbol] | 16 | ◯ |
| | coated film 15 | layered film 25 | | | |

### INDUSTRIAL APPLICABILITY

The present invention is suitably used for manufacturing black matrix for a color filter by an inkjet process in the field of flat panel displays such as liquid crystal displays, organic electroluminescence displays and plasma displays, and color filters used in such liquid crystal displays and organic electroluminescence displays.

1. A photopolymerizable resin layered film comprising a fluorine-containing compound layer and a photopolymerizable resin layer provided on a supporting film in that order,
characterized in that the fluorine-containing compound layer is formed by coating 1 to 60 mm³ of a composition containing 30 to 100% by mass of a fluorine-containing compound per 1 m² of the supporting film and has a contact angle to xylene of 20 degrees or more, and the photopolymerizable resin layer is composed of a photopolymerizable resin composition containing an alkali soluble polymer, a photopolymerizable compound having an ethylenically unsaturated bond, a photopolymerization initiator and a black pigment.

2. The photopolymerizable resin layered film according to claim 1, characterized in that the fluorine-containing compound is at least one selected from the group consisting of an amorphous fluorine resin, a copolymerization oligomer containing a perfluoroalkyl group-containing acrylate or methacrylate, a fluorine coating agent, a fluorine surfactant, a fluorine surface treatment agent containing an electron beam or ultraviolet light curable component and a fluorine surface treatment agent containing a thermosetting component.

3. A method for manufacturing a photopolymerizable resin layered film according to claim 1, characterized in that the method comprises:
a first layering step of providing, on a supporting film, a fluorine-containing compound layer which is formed by coating 1 to 60 mm³ of a composition containing 30 to 100% by mass of a fluorine-containing compound per 1 m² of the supporting film and which has a contact angle to xylene of 20 degrees or more; and
a second layering step of providing, on the fluorine-containing compound layer, a photopolymerizable resin layer composed of a photopolymerizable resin composition containing an alkali soluble polymer, a photopolymerizable compound having an ethylenically unsaturated bond, a photopolymerization initiator and a black pigment.

4. A method for manufacturing a photopolymerizable resin layered film according to claim 1, characterized in that the method comprises:
a first layering step of providing, on a first supporting film, a fluorine-containing compound layer which is formed by coating 1 to 60 mm³ of a composition containing 30 to 100% by mass of a fluorine-containing compound per 1 m² of the first supporting film and which has a contact angle to xylene of 20 degrees or more;
a second layering step of providing, on a second supporting film, a photopolymerizable resin layer composed of a photopolymerizable resin composition containing an alkali soluble polymer, a photopolymerizable compound having an ethylenically unsaturated bond, a photopolymerization initiator and a black pigment; and
a third layering step of laminating the surface of the photopolymerizable resin layer to the surface of the fluorine-containing compound layer.

5. A method for manufacturing a substrate having a black matrix pattern, at least comprising:
a layering step of laminating a photopolymerizable resin layered film according to claim 1 or 2 on a substrate so that the photopolymerizable resin layer comes into contact with the substrate;
an exposure step in which the resulting laminate is irradiated on the opposite side to the substrate with actinic ray through a photomask having a black matrix pattern; and
a developing step of developing the photopolymerizable resin layer and removing an unexposed portion thereof.

6. A method for manufacturing a substrate having a black matrix pattern, at least comprising:
a first layering step of providing, on a supporting film, a fluorine-containing compound layer which is formed by coating 1 to 60 mm³ of a composition containing 30 to 100% by mass of a fluorine-containing compound per 1 m² of the supporting film and which has a contact angle to xylene of 20 degrees or more;
a second layering step of providing, on a substrate, a photopolymerizable resin layer composed of a photopolymerizable resin composition containing an alkali soluble polymer, a photopolymerizable compound having an ethylenically unsaturated bond, a photopolymerization initiator and a black pigment;
a third layering step of laminating the surface of the photopolymerizable resin layer to the surface of the fluorine-containing compound layer, thereby preparing a photopolymerizable resin layered film according to claim 1 which is provided on the substrate;
an exposure step in which the resulting laminate is irradiated on the opposite side to the substrate with actinic ray through a photomask having a black matrix pattern; and
a developing step of developing the photopolymerizable resin layer and removing an unexposed portion thereof.

7. A method for manufacturing a substrate having a black matrix pattern according to claim 6, characterized in that the fluorine-containing compound is at least one selected from the group consisting of an amorphous fluorine resin, a copolymerization oligomer containing a perfluoroalkyl group-containing acrylate or methacrylate, a fluorine coating agent, a fluorine surfactant, a fluorine surface treatment agent containing an electron beam or ultraviolet light curable component and a fluorine surface treatment agent containing a thermosetting component.

8. A method for manufacturing a substrate having a black matrix pattern, at least comprising:
a first layering step of providing, on a substrate, a photopolymerizable resin layer composed of a photopolymerizable resin composition containing an alkali soluble polymer, a photopolymerizable compound having an ethylenically unsaturated bond, a photopolymerization initiator and a black pigment;
an exposure step in which the resulting laminate is irradiated on the opposite side to the substrate with actinic ray through a photomask having a black matrix pattern;
a developing step of developing the photopolymerizable resin layer and removing an unexposed portion thereof, thereby preparing a substrate having a black matrix pattern; and
a second layering step of attaching, on the black matrix pattern surface of the substrate having a black matrix pattern, a fluorine-containing compound layer side of a laminate with a fluorine-containing compound layer on a supporting film, which is formed by coating 1 to 60 mm³ of a composition containing 30 to 100% by mass of a fluorine-containing compound per 1 m² of the supporting film and which has a contact angle to xylene of 20 degrees or more.

9. A method for manufacturing a substrate having a black matrix pattern according to claim 8, characterized in that the fluorine-containing compound is at least one selected from the group consisting of an amorphous fluorine resin, a copolymerization oligomer containing a perfluoroalkyl group-containing acrylate or methacrylate, a fluorine coating agent, a fluorine surfactant, a fluorine surface treatment agent containing an electron beam or ultraviolet light curable component and a fluorine surface treatment agent containing a thermosetting component.

10. A method for manufacturing a color filter, characterized in that the method comprises:
a step of manufacturing a substrate having a black matrix pattern by a method according to any one of claims 5 to 9; and
a printing step of printing a thermosensitive or photopolymerizable color ink on at least a part of the substrate having a black matrix pattern, which is not covered with the black matrix pattern, by an inkjet process.
